(19) United States
(12) Patent Application Publication
(10) Pub. No.: US 2014/0375300 A1
(43) Pub. Date: Dec. 25, 2014

(54) PRINTED CIRCUIT BOARD, ELECTRONIC APPARATUS AND COMPONENT DETECTION METHOD

(71) Applicant: FUJITSU LIMITED, Kawasaki-shi (JP)

(72) Inventor: Ryota Tanaka, Kawasaki (JP)

(73) Assignee: FUJITSU LIMITED, Kawasaki-shi (JP)

(21) Appl. No.: 14/286,160

(22) Filed: May 23, 2014

(30) Foreign Application Priority Data
Jun. 25, 2013 (JP) 2013-132605

(51) Int. Cl. G01R 31/04

(52) U.S. Cl. CPC G01R 31/046
USPC 324/76.11

(57) ABSTRACT

A printed circuit board includes: a substrate, in which a hole for fixing a component is formed, in a first region, which is a region in which the component is detachably installed; a plurality of electrodes that are formed in the first region on the substrate; and a detection circuit that outputs detection signal corresponding to an aspect of an electrical connection between the plurality of electrodes and a fixing member that is fixed in the hole for installing the components on the substrate.

### CROSS-REFERENCE TO RELATED APPLICATION

This application is based upon and claims the benefit of priority of the prior Japanese Patent Application No. 2013-132605, filed on Jun. 25, 2013, the entire contents of which are incorporated herein by reference.

### FIELD

The embodiments discussed herein are related to a printed circuit board, an electronic apparatus and a component detection method.

### BACKGROUND

The installation of a component such as a module on a printed circuit board such as a motherboard using a connector or the like is widely performed in the related art.

A connector that fits a connector of a component is provided on a printed circuit board.

The installed component and the printed circuit board are electrically connected by interlocking the connector of the component with the connector of the printed circuit board.

Japanese Patent No. 3553141 and Japanese Laid-open Patent Publication No. 2006-109284 are examples of the related art.

There may be various aspects of components that can be installed on a printed circuit board using a connector.

For example, there may be plural kinds of storage capacities, or there may be cases in which modified components due to design changes and the like are to be used.

However, in the related art, it has not typically been easy to discriminate between those aspects of mounted components.

### SUMMARY

According to an aspect of the invention, a printed circuit board includes: a substrate, in which a hole for fixing a component is formed, in a first region, which is a region in which the component is detachably installed; a plurality of electrodes that are formed in the first region on the substrate; and a detection circuit that outputs detection signal corresponding to an aspect of an electrical connection between the plurality of electrodes and a fixing member that is fixed in the hole for installing the components on the substrate.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram that illustrates a printed circuit board according to a first embodiment;

FIG. 2 is a cross-sectional view that illustrates the printed circuit board according to the first embodiment;

FIGS. 3A and 3B are plan views that illustrate an electrode that is formed on the printed circuit board according to the first embodiment;

FIGS. 4A, 4B and 4C are plan views that illustrate examples of washers;

FIGS. 5A and 5B are a cross-sectional view and an equivalent circuit in a state in which a component A is not installed on the printed circuit board according to the first embodiment;

FIGS. 6A and 6B are a cross-sectional view and an equivalent circuit in a case in which a small-sized washer is used when fixing the component A to the printed circuit board according to the first embodiment;

FIGS. 7A and 7B are a cross-sectional view and an equivalent circuit in a case in which a medium-sized washer is used when fixing the component A to the printed circuit board according to the first embodiment;

FIGS. 8A and 8B are a cross-sectional view and an equivalent circuit in a case in which a large-sized washer is used when fixing the component A to the printed circuit board according to the first embodiment;

FIGS. 9A and 9B are a cross-sectional view and an equivalent circuit in a state in which a component B is not installed on the printed circuit board according to the first embodiment;

FIGS. 10A and 10B are a cross-sectional view and an equivalent circuit in a case in which a small-sized washer is used when fixing the component B to the printed circuit board according to the first embodiment;

FIGS. 11A and 11B are a cross-sectional view and an equivalent circuit in a case in which a medium-sized washer is used when fixing the component B to the printed circuit board according to the first embodiment;

FIGS. 12A and 12B are a cross-sectional view and an equivalent circuit in a case in which a large-sized washer is used when fixing the component B to the printed circuit board according to the first embodiment;

FIGS. 13A and 13B illustrate examples of tables that are stored in memory that is mounted in the printed circuit board according to the first embodiment;

FIG. 14 is a flowchart that illustrates a component detection method according to the first embodiment and a second embodiment;

FIG. 15 is a block drawing that illustrates a printed circuit board according to the second embodiment;

FIG. 16 is a cross-sectional view that illustrates the printed circuit board according to the second embodiment;

FIGS. 17A and 17B are plan views that illustrate an electrode that is formed on the printed circuit board according to the second embodiment;

FIGS. 18A and 18B are a cross-sectional view and an equivalent circuit in a state in which a component A is not installed on the printed circuit board according to the second embodiment;

FIGS. 19A and 19B are a cross-sectional view and an equivalent circuit in a case in which screw fastening is performed in a first hole when fixing component A to the printed circuit board according to the second embodiment;

FIGS. 20A and 20B are a cross-sectional view and an equivalent circuit in a case in which screw fastening is performed in a second hole when fixing component A to the printed circuit board according to the second embodiment;

FIGS. 21A and 21B are a cross-sectional view and an equivalent circuit in a case in which screw fastening is performed in both holes when fixing component A to the printed circuit board according to the second embodiment;

FIGS. 22A and 22B are a cross-sectional view and an equivalent circuit in a state in which a component B is not installed on the printed circuit board according to the second embodiment;

FIGS. 23A and 23B are a cross-sectional view and an equivalent circuit in a case in which screw fastening is performed in a first hole when fixing component B to the printed circuit board according to the second embodiment;

FIGS. 24A and 24B are a cross-sectional view and an equivalent circuit in a case in which screw fastening is performed in a second hole when fixing component B to the printed circuit board according to the second embodiment;

FIGS. 25A and 25B are a cross-sectional view and an equivalent circuit in a case in which screw fastening is performed in both holes when fixing component B to the printed circuit board according to the second embodiment; and

FIGS. 26A and 26B illustrate examples of tables that are stored in memory that is mounted in the printed circuit board according to the second embodiment.

### DESCRIPTION OF EMBODIMENTS

As described above, there are various aspects of components that are installed on printed circuit boards using connectors. For example, these can be cases in which there are a plurality of kinds of variations in which storage capacities differ, cases in which there are modified components that result from design changes, and the like.

Regardless of the requirement for differing controls and treatments depending on the aspect of components, information that indicates the aspect of installed components is written to memory that is mounted in the printed circuit board in cases in which a signal that indicates the aspect of the components is not output from the components. In such a case, since information that is written to the memory in advance differs for each aspect of installed component, a plurality of kinds of printed circuit board in which the information that is written to the memory differs mutually, are generated.

In addition to there being a plurality of aspects for a single component, an enormous number of kinds of printed circuit board are generated in cases in which the actual number of components that are installed using connectors is more than one, and management of the printed circuit board becomes difficult leading to an increase in costs.

### First Embodiment

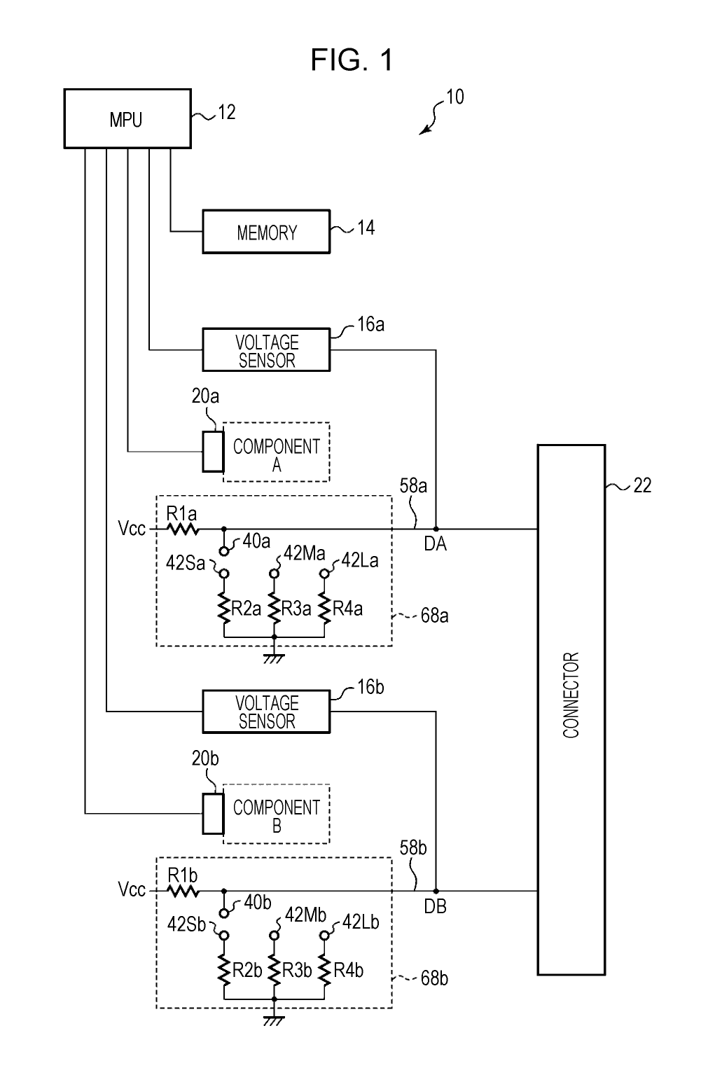

A printed circuit board, electronic apparatus and component detection method according to a first embodiment will be described using FIGS. 1 to 14.

### Printed Circuit Board and Electronic Apparatus

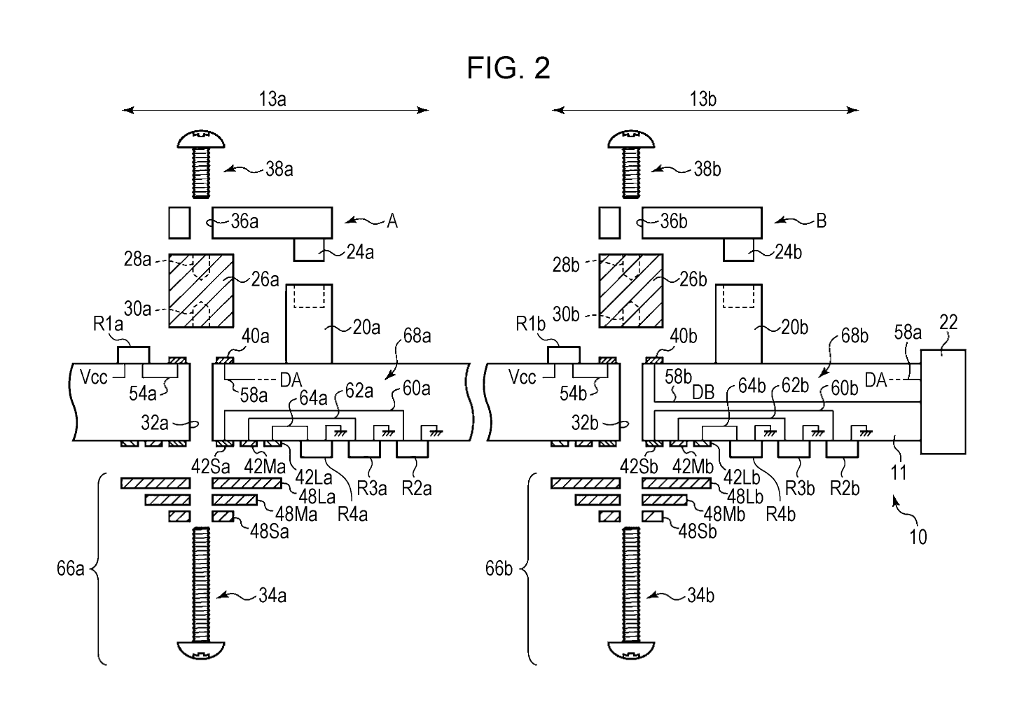

Firstly, the printed circuit board and the electronic apparatus according to the present embodiment will be described using FIGS. 1 to 13B. FIG. 1 is a block drawing that illustrates a printed circuit board according to the present embodiment. FIG. 2 is a cross-sectional view that illustrates the printed circuit board according to the present embodiment.

The electronic apparatus according to the present embodiment includes a printed circuit board 10 according to the present embodiment. The printed circuit board 10 is for example, a motherboard.

As illustrated in FIG. 1, the printed circuit board 10 according to the present embodiment includes a micro processing unit (MPU) 12 that executes predetermined processes, and a memory 14 in which firmware, tables and the like are stored. As the memory 14, for example, read only memory (ROM) or the like is used. As an interface of the MPU 12 and the memory 14, for example, a Serial Peripheral Interface (SPI) is used.

In addition, the printed circuit board 10 according to the present embodiment further includes voltage sensors (voltage monitors) 16a and 16b that measure the voltages of detection signals (an output signal and a present signal) DA and DB that are output from detection circuits (electrical circuits) 68a and 68b (to be described later). As interface of the MPU 12 and the voltage sensors 16a and 16b, for example, an Inter-Integrated Circuit (I²C) is used.

In addition, the printed circuit board 10 according to the present embodiment includes connectors (connectors for component installation and connectors for component mounting) 20a and 20b for installing for example, detachable components A and B on the printed circuit board 10 and a connector 22 for backplane for example. As an interface of the MPU 12 and the components A and B, for example, a Universal Serial Bus (USB) is used.

As a substrate (a base material) 11 of the printed circuit board 10, for example, a glass epoxy substrate or the like is used.

A component installation region (a component mounting region and a component mounting location) 13a, which is a region in which a component A is installed, is illustrated on the left-hand side of FIG. 2, and a component installation region (a component mounting region and a component mounting location) 13b, which is a region in which a component B is installed, is illustrated on the right-hand side of FIG. 2.

As the detachable components A and B, for example, a module (a module component) or the like is used. In this instance, a case in which the component A is for example, a solid state drive (SSD) will be described. In addition, here, a case in which the component B is for example, a Trusted Platform Module (TPM) will be described. An SSD is a storage device in which NAND-type flash memory is used as a storage medium. A TPM is a module that has a function of encrypting and decrypting data and a function of retaining key information that is used when encrypting and decrypting data.

Additionally, the components A and B are not limited to an SSD and a TPM.

The connectors 20a and 20b are provided inside the component installation regions 13a and 13b on a first surface side (an upper side in FIG. 2) of the printed circuit board 10. When the components A and B are installed in the component installation regions 13a and 13b, connectors 24a and 24b on a component A and B side and the connectors 20a and 20b on a printed circuit board 10 side respectively interlock.

When the components A and B are installed in the component installation regions 13a and 13b, for example, the components A and B are fixed to the printed circuit board 10 using conductive spacers (clearance ducts; members) 26a and 26b and the like. As the spacer 26a, for example, a double internal thread spacer or the like, in which an internal thread (a screw hole) 28a is formed in a first side, and an internal thread (a screw hole) 30a is also formed in a second side, is used. In addition, as the spacer 26b, for example, a double internal thread spacer or the like, in which an internal thread 28b is formed in a first side, and an internal thread 30b is also formed in a second side, is used. As a material of the spacers 26a and 26b, for example, stainless steel or the like is used. The external form of the spacer 26a is for example, cylindrical. The dimensions of the external forms of the spacers 26a and 26b are for example, configured to be approximately 1 cm in diameter, and approximately 2 cm in height. The internal diameters of the internal threads 28a and 30a that are formed in the spacer 26a are set to respectively accommodate the external diameters of external threads (screws) 38a and 34a that are used in screw fastening. The internal diameters of the internal threads 28b and 30b that are formed in the spacer 26b are set to respectively accommodate the external diameters of external threads 38b and 34b that are used in screw fastening.

Holes (penetration holes and holes for component fixing) 32a and 32b for fixing the spacers 26a and 26b to the printed circuit board 10 by screw fastening thereof are formed in the component installation regions 13a and 13b. The diameters of the holes 32a and 32b are set to be greater than the external diameters of the screws (fixing screws) 34a and 34b that are used in screw fastening. The holes 32a and 32b are clearance holes in which screw threads are not formed. In a case in which the external diameters of the screws 34a and 34b that are used in screw fastening are approximately 0.5 cm for example, the diameters of the holes 32a and 32b are for example, approximately 0.6 cm.

Holes (penetration holes) 36a and 36b for screw fastening the components A and B to the spacers 26a and 26b are formed in the components A and B. The diameters of the holes 36 are set to be greater than the external diameters of the screws 38a and 38b that are used in screw fastening. The holes 36 are clearance holes in which screw threads are not formed. In a case in which the external diameters of the screws (fixing screws) 38a and 38b that are used in screw fastening are approximately 0.5 cm for example, the diameters of the holes 36a and 36b is for example, approximately 0.6 cm.

Electrodes (electrode pads) 40a and 40b are respectively formed in the component installation regions 13a and 13b on the first surface side (the upper side in FIG. 2) of the printed circuit board 10.

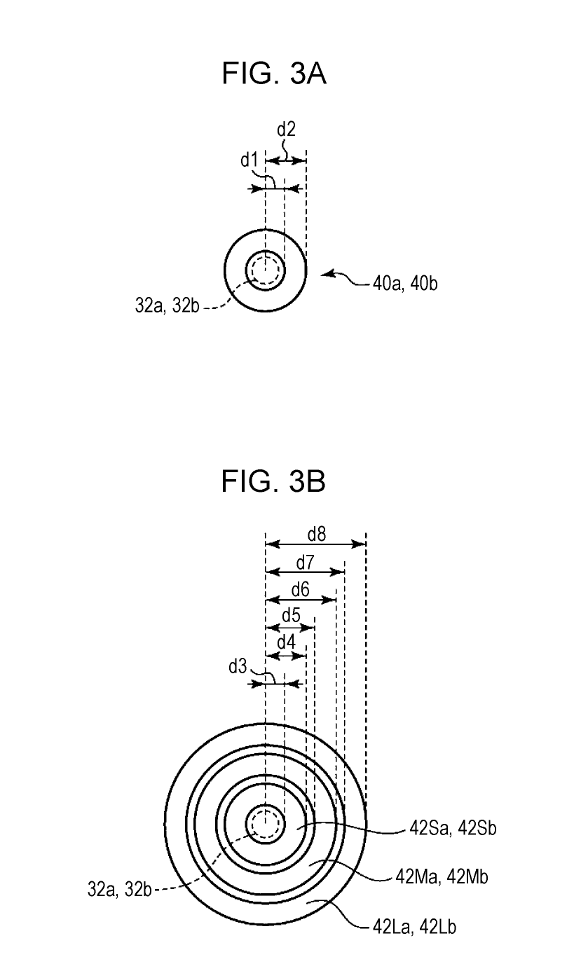

FIGS. 3A and 3B are plan views that illustrate an electrode that is formed on the printed circuit board according to the present embodiment. FIG. 3A illustrates an electrode that is formed on the first surface side of the printed circuit board according to the present embodiment.

As illustrated in FIG. 3A, the planar shapes of the electrodes 40a and 40b form for example, an annular shape (a ring shape). When the spacers 26a and 26b are arranged, lower surfaces of the spacers 26a and 26b come into contact with upper surfaces of the electrodes 40a and 40b. Therefore, the planar shapes of the electrodes 40a and 40b are set so as to correspond to the planar shapes of the spacers 26a and 26b. Internal radii d1 of the electrodes 40a and 40b are configured to be approximately 0.7 cm, for example. External radii d2 of the electrodes 40a and 40b are configured to be approximately 1 cm, for example.

A plurality of electrodes (electrode pads) 42Sa, 42Ma and 42La are formed in the component installation region 13a on a second surface side (a lower side in FIG. 2) of the printed circuit board 10. The electrodes 42Sa, 42Ma and 42La are formed in the periphery of the hole 32a.

In addition, a plurality of electrodes 42Sb, 42Mb and 42Lb are formed in the component installation region 13b on the second surface side (the lower side in FIG. 2) of the printed circuit board 10. The electrodes 42Sb, 42Mb and 42Lb are formed in the periphery of the hole 32b.

FIG. 3B illustrates an electrode that is formed on the second surface side of the printed circuit board according to the present embodiment.

As illustrated in FIG. 3B, the planar shapes of the electrodes 42Sa, 42Ma, 42La, 42Sb, 42Mb and 42Lb form for example, an annular shape (a ring shape).

The electrodes 42Sa, 42Ma and 42La are formed in a concentric fashion with the hole 32a as the center thereof. The electrodes 42Sb, 42Mb and 42Lb are formed in a concentric fashion with the hole 32b as the center thereof. In this instance, a case in which, for example, three kinds of electrode, large, medium and small 42La, 42Ma and 42Sa are formed in the periphery of the hole 32a, and three kinds of electrode, large, medium and small, 42Lb, 42Mb and 42Sb are formed in the periphery of the hole 32b, is described as an example.

External radii d4 of the small-sized electrodes 42Sa and 42Sb are respectively set to be greater than internal radii d3 of the small-sized electrodes 42Sa and 42Sb. Internal radii d5 of the medium-sized electrodes 42Ma and 42Mb are respectively set to be greater than the external radii d4 of the small-sized electrodes 42Sa and 42Sb. External radii d6 of the medium-sized electrodes 42Ma and 42Mb are respectively set to be greater than the internal radii d5 of the medium-sized electrodes 42Ma and 42Mb. Internal radii d7 of the large-sized electrodes 42La and 42Lb are respectively set to be greater than the external radii d6 of the medium-sized electrodes 42Ma and 42Mb. External radii d8 of the large-sized electrodes 42La and 42Lb are respectively set to be greater than the internal radii d7 of the large-sized electrodes 42La and 42Lb.

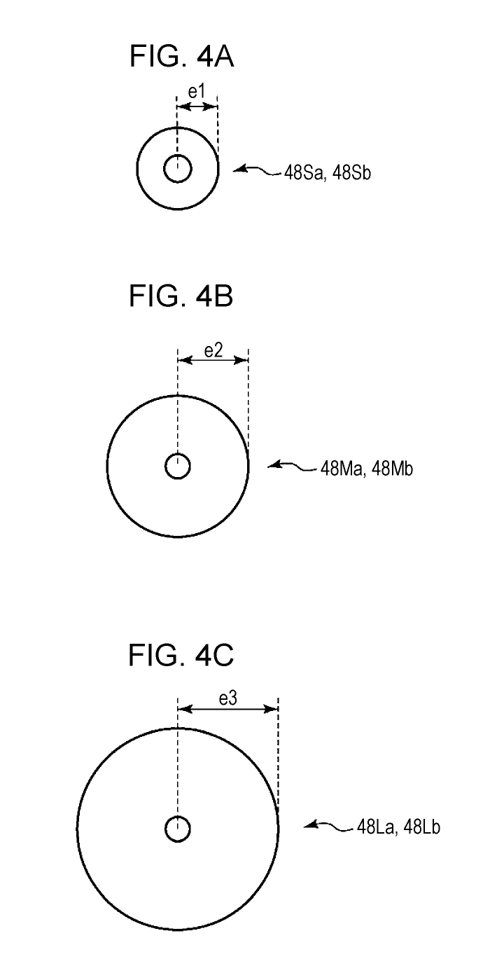

FIGS. 4A, 4B and 4C are plan views that illustrate examples of washers.

When the component A is attached to the printed circuit board 10, a lower portion of the spacer 26a is fixed to the printed circuit board 10 using the screw 34a and a washer. As the washer, for example, any one of three sizes of washer, large, medium and small, 48Sa, 48Ma and 48La are used selectively.

When the component B is attached to the printed circuit board 10, a lower portion of the spacer 26b is fixed to the printed circuit board 10 using the screw 34b and a washer. As the washer, for example, any one of three sizes of washer, large, medium and small, 48Sb, 48Mb and 48Lb are used selectively.

The internal radii d3 of the small-sized electrodes 42Sa and 42Sb are set to be smaller than external radii e1 of the small-sized washers 48Sa and 48Sb. In addition, the internal radii d5 of the medium-sized electrodes 42Ma and 42Mb are set to be greater than the external radii e1 of the small-sized washers 48Sa and 48Sb. Therefore, in a case in which screw fastening is performed using the small-sized washers 48Sa and 48Sb, the washers 48Sa and 48Sb come into contact with the small-sized electrodes 42Sa and 42Sb, but do not come into contact with the medium-sized electrodes 42Ma and 42Mb and the large-sized electrodes 42La and 42Lb.

In addition, the internal radii d5 of the medium-sized electrodes 42Ma and 42Mb are set to be smaller than external radii e2 of the medium-sized washers 48Ma and 48Mb. In addition, the internal radii d7 of the large-sized electrodes 42La and 42Lb are set to be greater than the external radii e2 of the medium-sized washers 48Ma and 48Mb. Therefore, in a case in which screw fastening is performed using the medium-sized washers 48Ma and 48Mb, the washers 48Ma and 48Mb come into contact with the small-sized electrodes 42Sa and 42Sb and the medium-sized electrodes 42Ma and 42Mb, but do not come into contact with the large-sized electrodes 42La and 42Lb.

In addition, the internal radii d7 of the large-sized electrodes 42La and 42Lb are set to be smaller than external radii e3 of the large-sized washers 48La and 48Lb. Therefore, in a case in which screw fastening is performed using the large-sized washers 48La and 48Lb, the washers 48La and 48Lb come into contact with the small-sized electrodes 42Sa and 42Sb, the medium-sized electrodes 42Ma and 42Mb and the large-sized electrodes 42La and 42Lb.

The internal radii e1 of the small-sized washers 48Sa and 48Sb are for example, configured to be approximately 0.7 cm. The external radii of the small-sized washers 48Sa and 48Sb are for example, configured to be approximately 1 cm.

The internal radii e2 of the medium-sized washers 48Ma and 48Mb are for example, configured to be approximately 0.7 cm. The external radii of the medium-sized washers 48Ma and 48Mb are for example, configured to be approximately 1.5 cm.

The internal radii e3 of the large-sized washers 48La and 48Lb are for example, configured to be approximately 0.7 cm. The external radii of the large-sized washers 48La and 48Lb are for example, configured to be approximately 2 cm.

The internal radii d3 of the small-sized electrodes 42Sa and 42Sb are for example, configured to be approximately 0.7 cm. The external radii d4 of the small-sized electrodes 42Sa and 42Sb are for example, configured to be approximately 1 cm.

The internal radii d5 of the medium-sized electrodes 42Ma and 42Mb are for example, configured to be approximately 1.2 cm. The external radii d6 of the medium-sized electrodes 42Ma and 42Mb are for example, configured to be approximately 1.5 cm.

The internal radii d7 of the large-sized electrodes 42La and 42Lb are for example, configured to be approximately 1.7 cm. The external radii d8 of the large-sized electrodes 42La and 42Lb are for example, configured to be approximately 2 cm.

The electrodes 40a and 40b that are formed on the surface of a first surface side of the printed circuit board 10, that is, the upper side in FIG. 1, are respectively connected to first end terminals of resistors (electrical resistors) R1a and R1b through wiring 54a and 54b. The electrical resistances of the resistors R1a and R1b are for example, respectively configured to be approximately 10 kΩ. Second end terminals of the resistors R1a and R1b are for example, respectively set to a power-supply voltage VCC. The power-supply voltage VCC is for example, configured to be approximately 3.3 V. In addition, signal lines 58a and 58b are respectively connected to the electrodes 40a and 40b. The signal lines 58a and 58b are for outputting detection signals DA and DB using detection circuits 68a and 68b (to be described later).

The small-sized electrodes 42Sa and 42Sb are respectively electrically connected to first terminal ends of resistors R2a and R2b through wiring 60a and 60b. The electrical resistances of the resistors R2a and R2b are for example, respectively configured to be approximately 10 kΩ. Second end terminals of the resistors R2a and R2b are for example, respectively connected to a grounding potential GND.

The medium-sized electrodes 42Ma and 42Mb are respectively electrically connected to first terminal ends of resistors R3a and R3b through wiring 62a and 62b. The electrical resistances of the resistors R3a and R3b are for example, respectively configured to be approximately 10 kΩ. Second end terminals of the resistors R3a and R3b are for example, respectively connected to a grounding potential GND.

The large-sized electrodes 42La and 42Lb are respectively electrically connected to first terminal ends of resistors R4a and R4b through wiring 64a and 64b. The electrical resistances of the resistors R4a and R4b are for example, respectively configured to be approximately 10 kΩ. Second end terminals of the resistors R4a and R4b are for example, respectively connected to a grounding potential GND.

When the component A is installed, either one of the plurality of washers 48Sa, 48Ma, and 48La is selected. One of the plurality of washers 48Sa, 48Ma, and 48La is arranged on a lower surface side of an electrode 42a, the screw 34a passes through the hole 32a, and screw fastening is performed. According to this configuration, the component A is fixed to the printed circuit board 10 through the spacer 26a using a member for fixing 66a that includes one of the washers 48Sa, 48Ma, and 48La and the screw 34a.

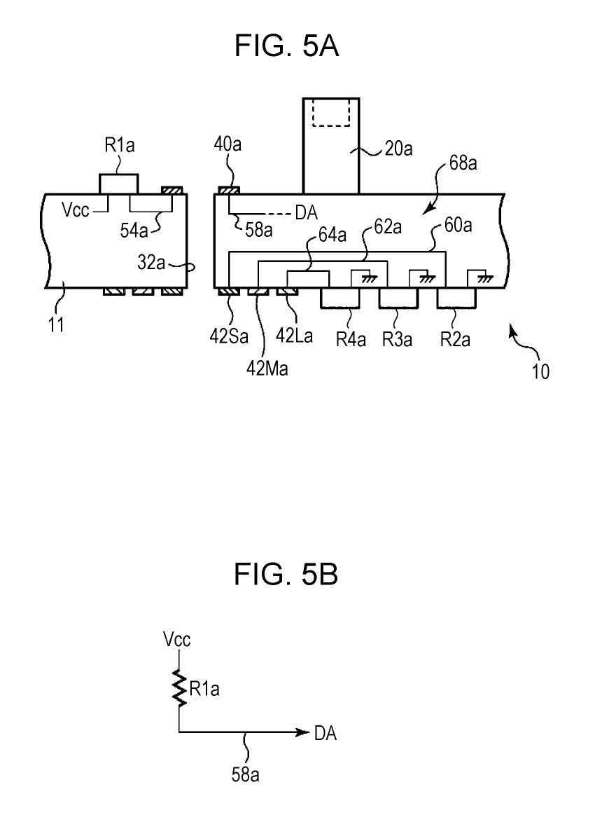

FIGS. 5A and 5B are a cross-sectional view and an equivalent circuit in a state in which the component A is not installed on the printed circuit board according to the present embodiment. FIG. 5A illustrates a cross-sectional view and FIG. 5B illustrates an equivalent circuit.

As illustrated in FIG. 5A, in a case in which the component A is not installed on the printed circuit board 10, the spacer 26a, a washer 48a and the screw 34a are not attached. Therefore, the electrode 40a that is formed on an upper surface side of the printed circuit board 10 and the electrode 42a that is formed on the lower surface side of the printed circuit board 10 are not electrically connected through the screw 34a and a washer 48a. In this case, an equivalent circuit such as that illustrated in FIG. 5B is formed, and the voltage of the signal line 58a, that is, the voltage of the detection signal DA becomes approximately 3.3 V for example, a voltage that is equivalent to the power-supply voltage VCC for example.

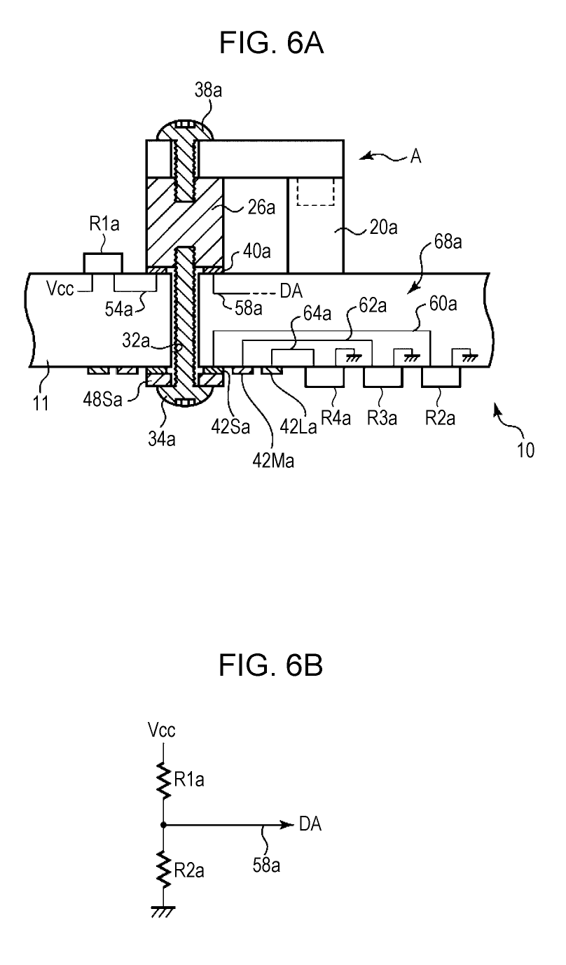

FIGS. 6A and 6B are a cross-sectional view and an equivalent circuit in a case in which the small-sized washer is used when fixing the component A to the printed circuit board according to the present embodiment. FIG. 6A illustrates a cross-sectional view and FIG. 6B illustrates an equivalent circuit.

As illustrated in FIG. 6A, in a case in which the small-sized washer 48Sa is selected when fixing the component A, the small-sized washer 48Sa comes into contact with the small-sized electrode 42Sa. The small-sized washer 48Sa does not come into contact with the medium-sized electrode 42Ma or the large-sized electrode 42La. The small-sized electrode 42Sa that is formed on the lower surface side of the printed circuit board 10 and the electrode 40a that is formed on the upper surface side of the printed circuit board 10 are electrically connected through the small-sized washer 48Sa and the screw 34a. In this case, an equivalent circuit such as that illustrated in FIG. 6B is formed, and the voltage of the signal line 58a, that is, the voltage of the detection signal DA becomes approximately 1.65 V for example.

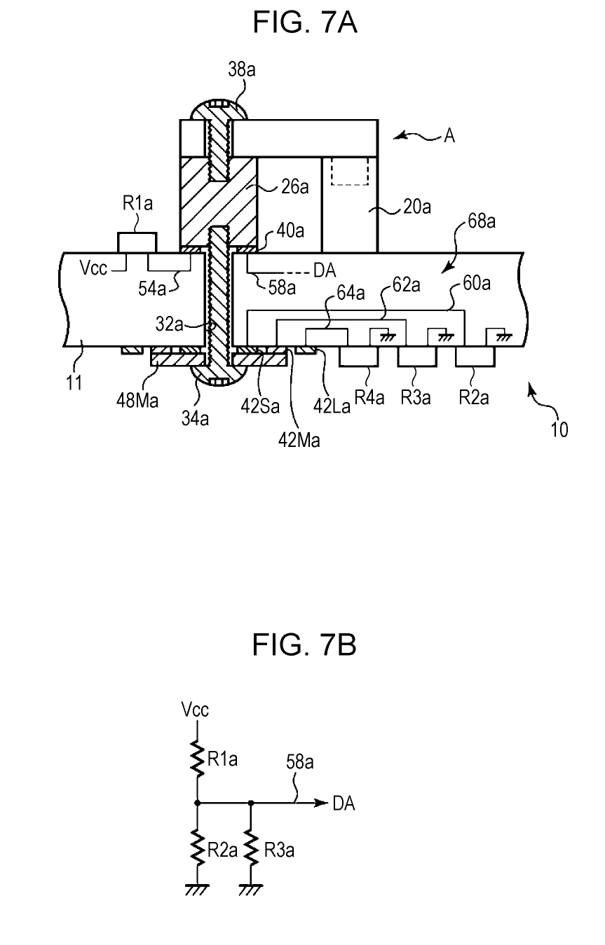

FIGS. 7A and 7B are a cross-sectional view and an equivalent circuit in a case in which the medium-sized washer is used when fixing the component A to the printed circuit board according to the present embodiment. FIG. 7A illustrates a cross-sectional view and FIG. 7B illustrates an equivalent circuit.

As illustrated in FIG. 7A, in a case in which the medium-sized washer 48Ma is selected when fixing the component A, the medium-sized washer 48Ma comes into contact with the small-sized electrode 42Sa and the medium-sized electrode 42Ma. The medium-sized washer 48Ma does not come into contact with the large-sized electrode 42La. The small-sized electrode 42Sa and the medium-sized electrode 42Ma that are formed on the lower surface side of the printed circuit board 10 and the electrode 40a that is formed on the upper surface side of the printed circuit board 10 are electrically connected through the medium-sized washer 48Ma and the screw 34a. In this case, an equivalent circuit such as that illustrated in FIG. 7B is formed, and the voltage of the signal line 58a, that is, the voltage of the detection signal DA becomes approximately 1.1 V for example.

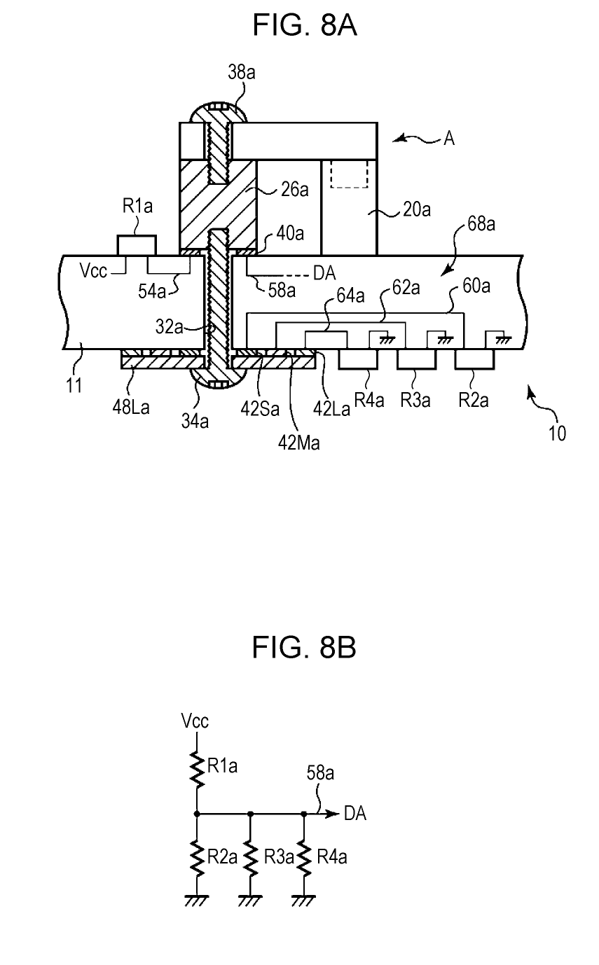

FIGS. 8A and 8B are a cross-sectional view and an equivalent circuit in a case in which a large-sized washer is used when fixing the component A to the printed circuit board according to the present embodiment. FIG. 8A illustrates a cross-sectional view and FIG. 8B illustrates an equivalent circuit.

As illustrated in FIG. 8A, in a case in which the large-sized washer 48La is selected when fixing the component A, the large-sized washer 48La comes into contact with the small-sized electrode 42Sa, the medium-sized electrode 42Ma and the large-sized electrode 42La. The small-sized electrode 42Sa, the medium-sized electrode 42Ma and the large-sized electrode 42La that are formed on the lower surface side of the printed circuit board 10 and the electrode 40a that is formed on the upper surface side of the printed circuit board 10 are electrically connected through the washer 48La and the screw 34a. In this case, an equivalent circuit such as that illustrated in FIG. 8B is formed, and the voltage of the signal line 58a, that is, the voltage of the detection signal DA becomes approximately 0.8 V for example.

When the component A is installed, screw fastening is performed using a washer depending on aspects such as the kind (type) or the revision number (revision) of an installed component A.

For example, a configuration in which it is determined in advance that fixing is performed using the small-sized washer 48Sa for example, is employed in a case in which a type 1 component A is installed.

In addition, for example, a configuration in which it is determined in advance that fixing is performed using the medium-sized washer 48Ma for example, is employed in a case in which a type 2 component A is installed.

In addition, for example, a configuration in which it is determined in advance that fixing is performed using the large-sized washer 48La for example, is employed in a case in which a type 3 component A is installed.

Therefore, the voltage of the signal line 58a, that is, the voltage of the detection signal DA becomes a voltage that corresponds to the type of an installed component A.

When the component B is installed, either one of the plurality of washers 48Sb, 48Mb, and 48Lb is selected. One of the plurality of washers 48Sb, 48Mb, and 48Lb is arranged on a lower surface side of an electrode 42b, the screw 34b passes through the hole 32b, and screw fastening is performed. According to this configuration, the component B is fixed to the printed circuit board 10 through the spacer 26b using a member for fixing 66b that includes one of the washers 48Sb, 48Mb, and 48Lb and the screw 34b.

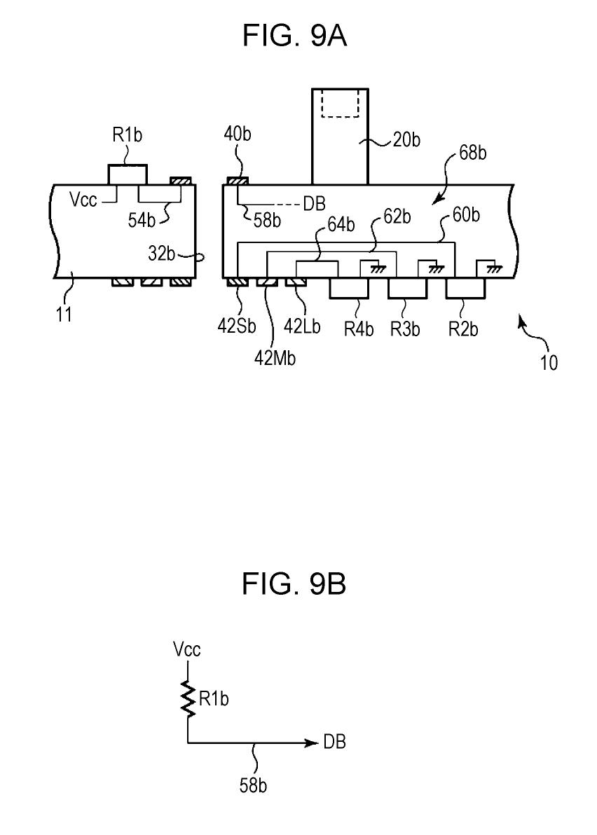

FIGS. 9A and 9B are a cross-sectional view and an equivalent circuit in a state in which the component B is not installed on the printed circuit board according to the present embodiment. FIG. 9A illustrates a cross-sectional view and FIG. 9B illustrates an equivalent circuit.

As illustrated in FIG. 9A, in a case in which the component B is not installed on the printed circuit board 10, the spacer 26b, a washer 48b and the screw 34b are not attached. Therefore, the electrode 40b that is formed on an upper surface side of the printed circuit board 10 and the electrode 42b that is formed on the lower surface side of the printed circuit board 10 are not electrically connected through the screw 34b and a washer 48b. In this case, an equivalent circuit such as that illustrated in FIG. 9B is formed, and the voltage of the signal line 58b, that is, the voltage of the detection signal DB becomes approximately 3.3 V for example, a voltage that is equivalent to the power-supply voltage VCC for example.

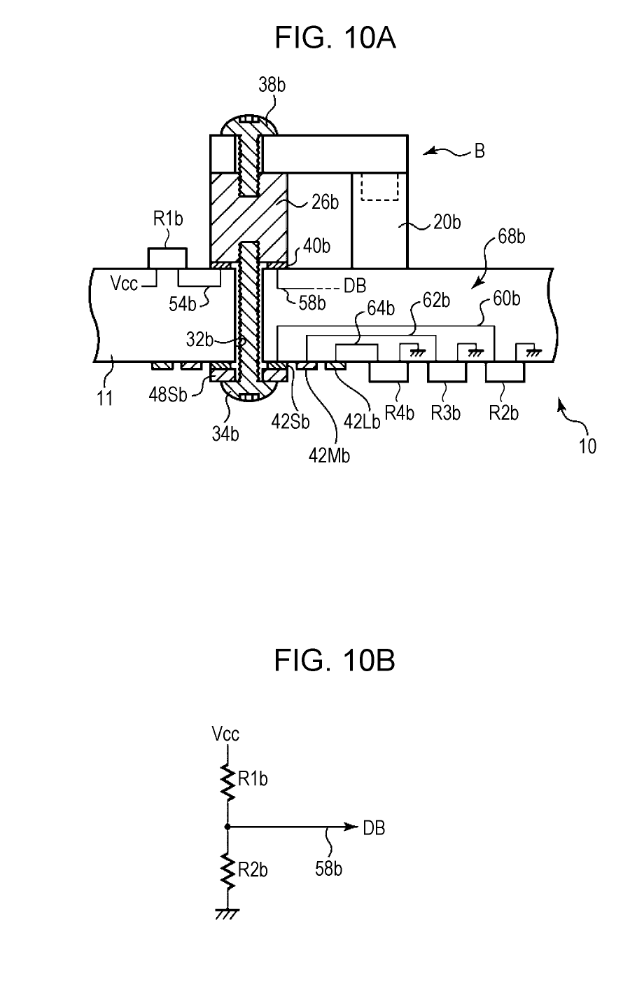

FIGS. 10A and 10B are a cross-sectional view and an equivalent circuit in a case in which the small-sized washer is used when fixing the component B to the printed circuit board according to the present embodiment. FIG. 10A illustrates a cross-sectional view and FIG. 10B illustrates an equivalent circuit.

As illustrated in FIG. 10A, in a case in which the small-sized washer 48Sb is selected when fixing the component B, the small-sized washer 48Sb comes into contact with the small-sized electrode 42Sb. The small-sized washer 48Sb does not come into contact with the medium-sized electrode 42Mb or the large-sized electrode 42Lb. The small-sized electrode 42Sb that is formed on the lower surface side of the printed circuit board 10 and the electrode 40b that is formed on the upper surface side of the printed circuit board 10 are electrically connected through the small-sized washer 48Sb and the screw 34b. In this case, an equivalent circuit such as that illustrated in FIG. 10B is formed, and the voltage of the signal line 58b, that is, the voltage of the detection signal DB becomes approximately 1.65 V for example.

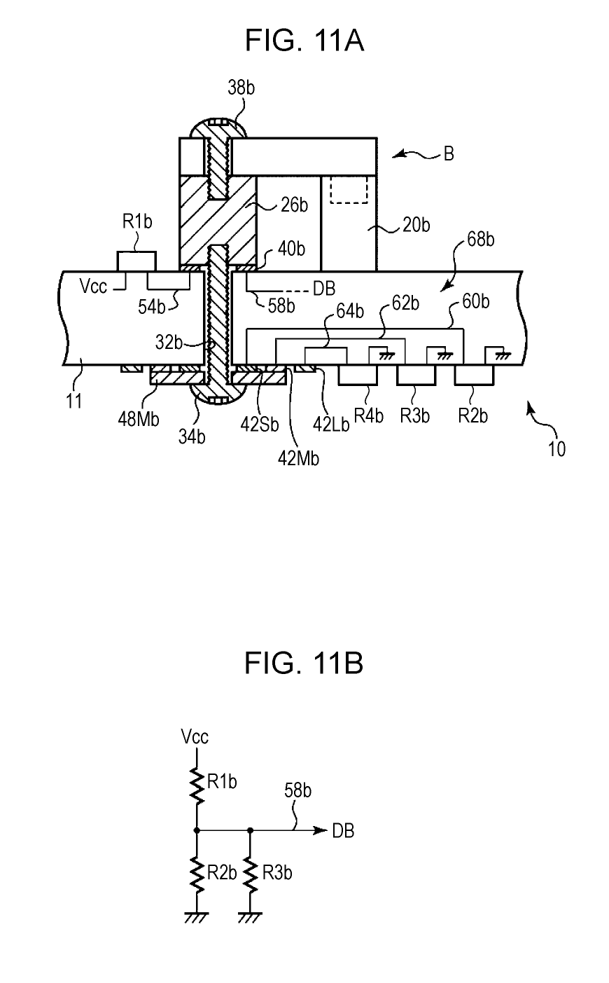

FIGS. 11A and 11B are a cross-sectional view and an equivalent circuit in a case in which the medium-sized washer is used when fixing the component B to the printed circuit board according to the present embodiment. FIG. 11A illustrates a cross-sectional view and FIG. 11B illustrates an equivalent circuit.

As illustrated in FIG. 11A, in a case in which the medium-sized washer 48Mb is selected when fixing the component B, the medium-sized washer 48Mb comes into contact with the small-sized electrode 42Sb and the medium-sized electrode 42Mb. The medium-sized washer 48Mb does not come into contact with the large-sized electrode 42Lb. The small-sized electrode 42Sb and the medium-sized electrode 42Mb that are formed on the lower surface side of the printed circuit board 10 and the electrode 40b that is formed on the upper surface side of the printed circuit board 10 are electrically connected through the medium-sized washer 48Mb and the screw 34b. In this case, an equivalent circuit such as that illustrated in FIG. 11B is formed, and the voltage of the signal line 58b, that is, the voltage of the detection signal DB becomes approximately 1.1 V for example.

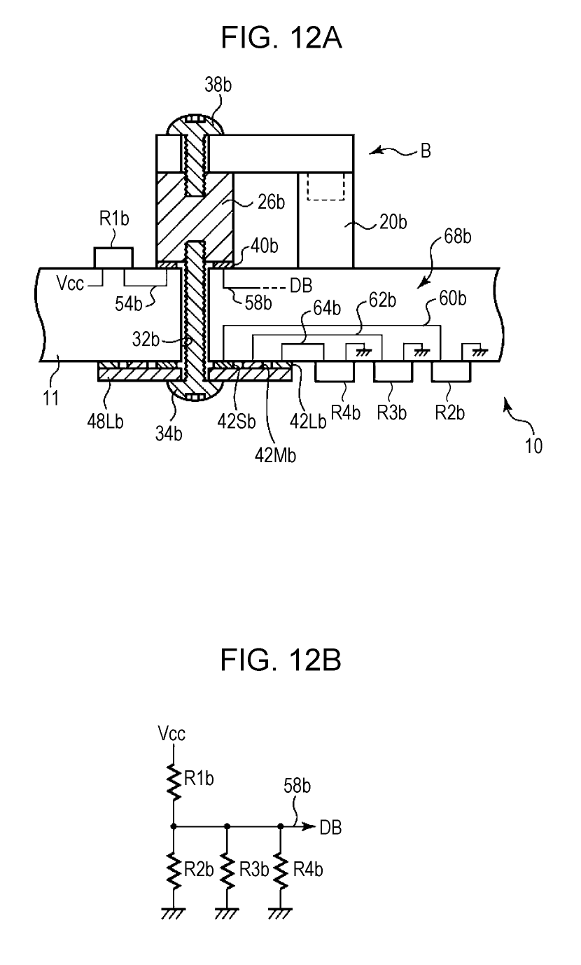

FIGS. 12A and 12B are a cross-sectional view and an equivalent circuit in a case in which a large-sized washer is used when fixing the component B to the printed circuit board according to the present embodiment. FIG. 12A illustrates a cross-sectional view and FIG. 12B illustrates an equivalent circuit.

As illustrated in FIG. 12A, in a case in which the large-sized washer 48Lb is selected when fixing the component B, the washer 48Lb comes into contact with the small-sized electrode 42Sb, the medium-sized electrode 42Mb and the large-sized electrode 42Lb. The small-sized electrode 42Sb, the medium-sized electrode 42Mb and the large-sized electrode 42Lb that are formed on the lower surface side of the printed circuit board 10 and the electrode 40b that is formed on the upper surface side of the printed circuit board 10 are electrically connected through the washer 48Lb and the screw 34b. In this case, an equivalent circuit such as that illustrated in FIG. 12B is formed, and the voltage of the signal line 58b, that is, the voltage of the detection signal DB becomes approximately 0.8 V for example.

When the component B is installed, screw fastening is performed using a washer depending on aspects such as the kind (type) or the revision number (revision) of an installed component B.

For example, a configuration in which it is determined in advance that fixing is performed using the small-sized washer 48Sb for example, is employed in a case in which a revision 1.0 component B is installed.

In addition, for example, a configuration in which it is determined in advance that fixing is performed using the medium-sized washer 48Mb for example, is employed in a case in which a revision 1.1 component is installed.

In addition, for example, a configuration in which it is determined in advance that fixing is performed using the large-sized washer 48Lb for example, is employed in a case in which a revision 1.2 component is installed.

Therefore, the voltage of the signal line 58b, that is, the voltage of the detection signal DB becomes a voltage that corresponds to the presence or absence of installation of the component B and the revision of an installed component B.

In this manner, in the present embodiment, a detection circuit (an electrical circuit) 68a that includes the electrodes 40a, 42Sa, 42Ma and 42La, and the resistors R1a, R2a, R3a and R4a, and outputs a detection signal DA with a voltage depending on the presence or absence of installation of the component A and the aspect of an installed component A, is formed.

In addition, a detection circuit (an electrical circuit) 68b that includes the electrodes 40b, 42Sb, 42Mb and 42Lb, and the resistors R1b, R2b, R3b and R4b, and outputs a detection signal DB with a voltage depending on the presence or absence of installation of the component B and the aspect of an installed component B, is formed.

As illustrated in FIG. 1, the output signal line 58a of the detection circuit 68a is connected to an input terminal end of the voltage sensor 16a. The voltage sensor 16a measures the voltage of the output signal line 58a of the detection circuit 68a, that is, the voltage of the detection signal DA, and is a sensor that outputs measured voltage data of the detection signal DA. As the voltage sensor 16a, for example, a system monitor (model number: MAX16031) manufactured by MAXIM Integrated is used.

The output of the voltage sensor 16a is input into the MPU 12. The data of the voltage of the detection signal DA that is measured by the voltage sensor 16a is read by the MPU 12.

In addition, the output signal line 58b of the detection circuit 68b is connected to an input terminal end of the voltage sensor 16b. The voltage sensor 16b measures the voltage of the output signal line 58b of the detection circuit 68b, that is, the voltage of the detection signal DB, and is a sensor that outputs measured voltage data of the detection signal DB. As the voltage sensor 16b, it is possible to use the same sensor as that of the voltage sensor 16a.

The output of the voltage sensor 16b is input into the MPU 12. The data of the voltage of the detection signal DB that is measured by the voltage sensor 16b is read by the MPU 12.

The detection signals DA and DB that are output from the detection circuits 68a and 68b are output to the outside through the connector 22 in addition to being input to the voltage sensors 16a and 16b.

Tables that indicate correspondence relationships between the voltage of the detection signal DA and the aspect of the component A are stored in the memory 14.

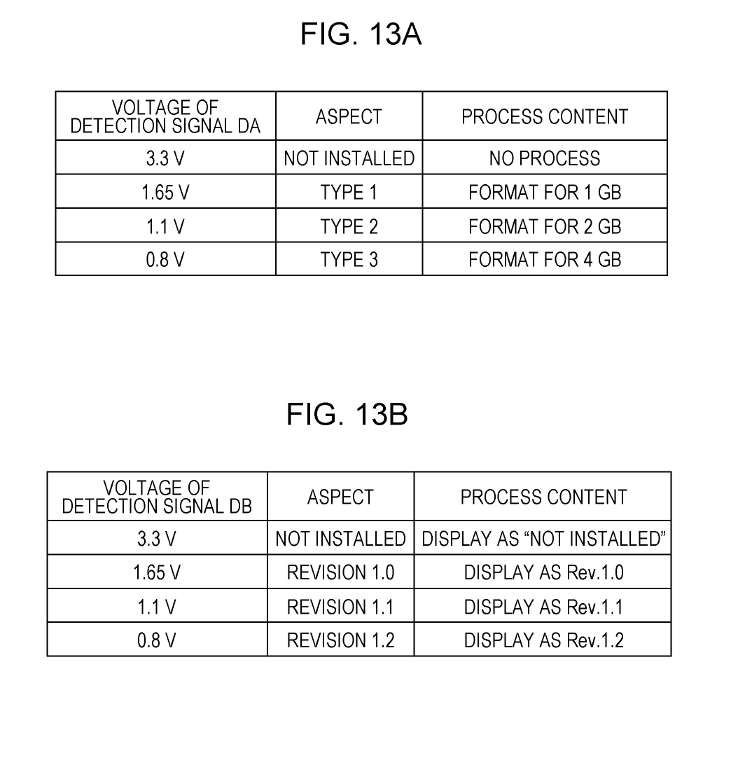

FIGS. 13A and 13B illustrate examples of tables that are stored in the memory that is mounted in the printed circuit board according to the present embodiment. FIG. 13A illustrates a table that relates to the component A.

As illustrated in FIG. 13A, process content that corresponds to the voltage of the detection signal DA of the detection circuit 68a is indicated in the table that corresponds to the component A.

In the manner mentioned above, the voltage of the detection signal DA becomes approximately 3.3 V for example, in a case in which the component A is not installed (not installed). The process content of a case in which the voltage of the detection signal DA is approximately 3.3 V is “no process”. Therefore, in this case, the MPU 12 does not perform any processes on the component A.

A type 1 component A is an SSD with a capacity of 1 GB, for example. As mentioned above, in a case in which a type 1 component A is installed, the voltage of the detection signal DA becomes approximately 1.65 V, for example. The process content of a case in which the voltage of the detection signal DA is for example, approximately 1.65 V is “format for 1 GB”. Therefore, in this case, the MPU 12 performs a process that formats the component A for 1 GB.

A type 2 component A is an SSD with a capacity of 2 GB, for example. As mentioned above, in a case in which a type 2 component A is installed, the voltage of the detection signal DA becomes approximately 1.1 V, for example. The process content of a case in which the voltage of the detection signal DA is for example, approximately 1.1 V is “format for 2 GB”. Therefore, in this case, the MPU 12 performs a process that formats the component A for 2 GB.

A type 3 component A is an SSD with a capacity of 4 GB, for example. As mentioned above, in a case in which a type 3 component A is installed, the voltage of the detection signal DA becomes approximately 0.8 V, for example. The process content of a case in which the voltage of the detection signal DA is for example, approximately 0.8 V is “format for 4 GB”. Therefore, in this case, the MPU 12 performs a process that formats the component A for 4 GB.

FIG. 13B illustrates a table that relates to the component B.

As illustrated in FIG. 13B, process content that corresponds to the voltage of the detection signal DB is indicated in the table that corresponds to the component B.

In the manner mentioned above, the voltage of the detection signal DB becomes approximately 3.3 V for example, in a case in which the component B is not installed (not installed). The process content of a case in which the voltage of the detection signal DB is approximately 3.3 V is “display not installed”. Therefore, in this case, the MPU 12 displays that the component B is “not installed” using a display screen (not illustrated in the drawings).

As mentioned above, in a case in which a revision 1.0 component B is installed, the voltage of the detection signal DB becomes approximately 1.65 V, for example. The process content of a case in which the voltage of the detection signal DB is for example, approximately 1.65 V is “display Rev. 1.0”. Therefore, in this case, the MPU 12 displays “Rev. 1.0” using the display screen.

As mentioned above, in a case in which a revision 1.1 component B is installed, the voltage of the detection signal DB becomes approximately 1.1 V, for example. The process content of a case in which the voltage of the detection signal DB is for example, approximately 1.1 V is “display Rev. 1.1”. Therefore, in this case, the MPU 12 displays “Rev. 1.1” using a display screen.

As mentioned above, in a case in which a revision 1.2 component B is installed, the voltage of the detection signal DB becomes approximately 0.8 V, for example. The process content of a case in which the voltage of the detection signal DB is for example, approximately 0.8 V is “display Rev. 1.2”. Therefore, in this case, the MPU 12 displays “Rev. 1.2” using the display screen.

The printed circuit board 10 according to the present embodiment is formed according to this configuration.

### Component Detection Method

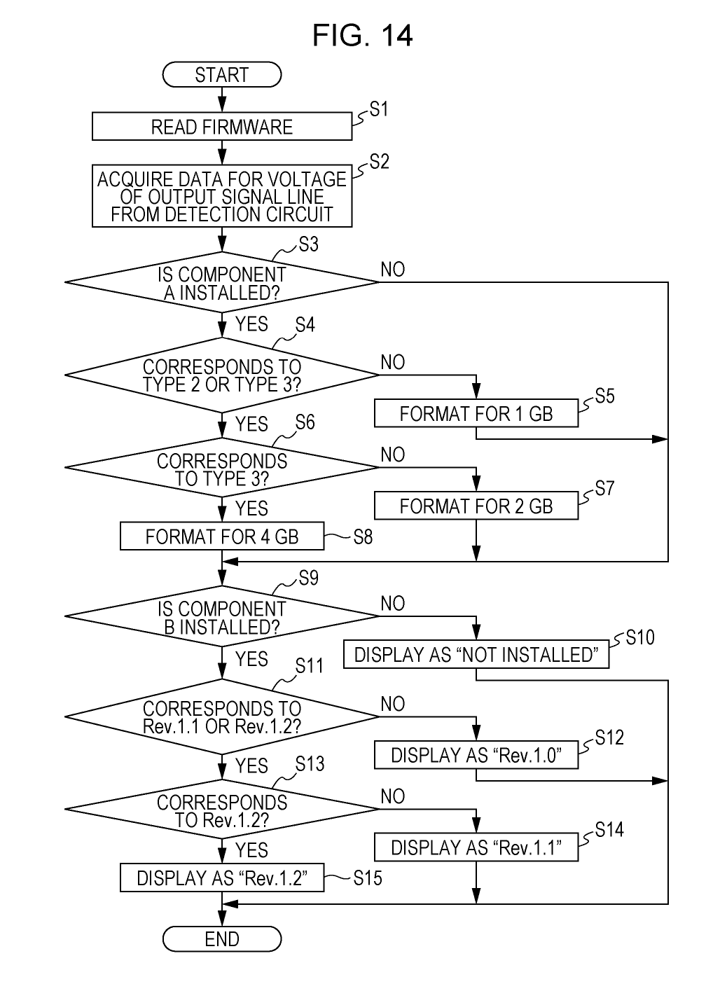

Next, a component detection method according to the present embodiment will be described using FIG. 14. FIG. 14 is a flowchart that illustrates a component detection method according to the present embodiment.

Firstly, when the printed circuit board 10 is powered on, the MPU 12 reads firmware that is stored in the memory 14 and initiates predetermined processes (STEP 51).

Next, the MPU 12 acquires data for the voltage of the output signal line 58a of the detection circuit 68a that is measured by the voltage sensor 16a. In addition, the MPU 12 acquires data for the voltage of the output signal line 58b of the detection circuit 68b that is measured by the voltage sensor 16b (STEP S2).

Next, it is determined whether or not a component A is installed (STEP S3). Whether or not a component A is installed is determined by whether or not the voltage of the output signal line 58a of the detection circuit 68a is for example, approximately 3.3 V. More specifically, it is determined whether or not the voltage of the output signal line 58a of the detection circuit 68a is higher than a predetermined threshold voltage. For example, a voltage between 1.65 V and 3.3 V can be configured as the threshold voltage. In a case in which the voltage of the output signal line 58a of the detection circuit 68a is higher than the threshold voltage, since a component A is not installed, the MPU 12 does not perform any processes on the component A. In a case in which the voltage of the output signal line 58a of the detection circuit 68a is lower than the threshold voltage, the MPU 12 determines that a component A is installed.

In a case in which it is determined that a component A is installed, the MPU 12 determines whether or not the component A corresponds to a type 2 or a type 3 (STEP S4). Whether or not the installed component A corresponds to a type 2 or a type 3 is determined by whether or not the voltage of the output signal line 58a of the detection circuit 68a is for example, approximately 1.65 V. More specifically, it is determined whether or not the voltage of the output signal line 58a of the detection circuit 68a is higher than a predetermined threshold voltage. For example, a voltage between 1.1 V and 1.65 V can be configured as the threshold voltage. In a case in which the voltage of the output signal line 58a of the detection circuit 68a is higher than the threshold voltage, the MPU 12 determines that the component A is a type 1, and formats the component A for 1 GB (STEP S5). In a case in which the voltage of the output signal line 58a of the detection circuit 68a is lower than the threshold voltage, the MPU 12 determines that the component A corresponds to a type 2 or a type 3.

In a case in which it is determined that the component A corresponds to a type 2 or a type 3, the MPU 12 determines whether or not the component A corresponds to a type 3 (STEP S6). Whether or not the installed component A corresponds to a type 3 is determined by whether or not the voltage of the output signal line 58a of the detection circuit 68a is for example, approximately 1.1 V. More specifically, it is determined whether or not the voltage of the output signal line 58a of the detection circuit 68a is higher than a predetermined threshold voltage. For example, a voltage between 0.8 V and 1.1 V can be configured as the threshold voltage. In a case in which the voltage of the output signal line 58a of the detection circuit 68a is higher than the threshold voltage, the MPU 12 determines that the component A is a type 2, and formats the component A for 2 GB (STEP S7). In a case in which the voltage of the output signal line 58a of the detection circuit 68a is lower than the threshold voltage, the MPU 12 determines that the component A is a type 3, and formats the component A for 4 GB (STEP S8).

In a case in which determination with respect to a component B that is installed in a different location, is also desired, determination with respect to the component B in a different location is also performed subsequently.

That is, it is determined whether or not a component B is installed (STEP S9). Whether or not a component B is installed is determined by whether or not the voltage of the output signal line 58b of the detection circuit 68b is for example, approximately 3.3 V. More specifically, it is determined whether or not the voltage of the output signal line 58b of the detection circuit 68b is higher than a predetermined threshold voltage. For example, a voltage between 1.65 V and 3.3 V can be configured as the threshold voltage. In a case in which the voltage of the output signal line 58b of the detection circuit 68b is higher than the threshold voltage, since a component B is not installed, the MPU 12 displays that the component B is “not installed” using a display screen (not illustrated in the drawings) (STEP S10). In a case in which the voltage of the output signal line 58b of the detection circuit 68b is lower than the threshold voltage, the MPU 12 determines that a component B is installed.

In a case in which it is determined that a component B is installed, the MPU 12 determines whether or not the component B corresponds to a revision 1.1 or a revision 1.2 (STEP S11). Whether or not the installed component B corresponds to a revision 1.1 or a revision 1.2 is determined by whether or not the voltage of the output signal line 58b of the detection circuit 68b is for example, approximately 1.65 V. More specifically, it is determined whether or not the voltage of the output signal line 58b of the detection circuit 68b is higher than a predetermined threshold voltage. For example, a voltage between 1.1 V and 1.65 V can be configured as the threshold voltage. In a case in which the voltage of the output signal line 58b of the detection circuit 68b is higher than the threshold voltage, the MPU 12 determines that the component B is a revision 1.0, and displays that the component B is “Rev. 1.0” using the display screen (STEP S12).

In a case in which it is determined that the component B corresponds to a revision 1.1 or a revision 1.2, the MPU 12 determines whether or not the component B corresponds to a revision 1.2 (STEP S13). Whether or not the installed component B corresponds to a revision 1.2 is determined by whether or not the voltage of the output signal line 58b of the detection circuit 68b is for example, approximately 1.1 V. More specifically, it is determined whether or not the voltage of the output signal line 58b of the detection circuit 68b is higher than a predetermined threshold voltage. For example, a voltage between 0.8 V and 1.1 V can be configured as the threshold voltage. In a case in which the voltage of the output signal line 58b of the detection circuit 68b is higher than the threshold voltage, the MPU 12 determines that the component B is a revision 1.1, and displays that the component B is “Rev. 1.1” using the display screen (STEP S14).

In a case in which the voltage of the output signal line 58b of the detection circuit 68b is lower than the threshold voltage, the MPU 12 determines that the component B is a revision 1.2, and displays that the component B is “Rev. 1.2” using the display screen (STEP S15).

According to this configuration, the presence or absence of installation of the components A and B and the aspects of the kinds and revision numbers of installed components A and B are determined and processes are performed depending on the determination result.

In this manner, according to the present embodiment, the holes 32a and 32b for fixing the components A and B and the plurality of electrodes 42Sa, 42Ma, 42La, 42Sb, 42Mb and 42Lb are formed in the component installation regions 13a and 13b in which detachable components A and B are installed. Detection circuits 68a and 68b, which output detection signals DA and DB depending on the aspects of the electrical connections of the members for fixing 66a and 66b that are arranged in the holes 32a and 32b when fixing components A and B to the plurality of electrodes 42Sa, 42Ma, 42La, 42Sb, 42Mb and 42Lb, are provided. The aspects of installed components A and B are associated with the members for fixing 66a and 66b that are arranged in the holes 32a and 32b for fixing the components A and B. Therefore, it is possible to easily determine the presence or absence of installation of the components A and B, the aspects of installed components A and B and the like based on the detection signals DA and DB of the detection circuits 68a and 68b. Therefore, variation of the content that is written to the memory 14 in advance for the presence or absence of installation of the components A and B and each aspect of installed components A and B, is not desired. Therefore, it is possible to suppress the generation of a plurality of kinds of printed circuit board 10 in which the information that is written to the memory 14 differs mutually, it is possible to suppress complications in the management of the printed circuit board 10, and furthermore, it is possible to contribute to a reduction in cost.

### Second Embodiment

A printed circuit board, electronic apparatus and component detection method according to a second embodiment will be described using FIGS. 14 to 26B. The same reference symbols will be given to constituent elements that are the same as those in the printed circuit board, electronic apparatus and component detection method according to the first embodiment that are illustrated in FIGS. 1 to 14, and description thereof will be omitted or stated in brief.

### Printed Circuit Board and Electronic Apparatus

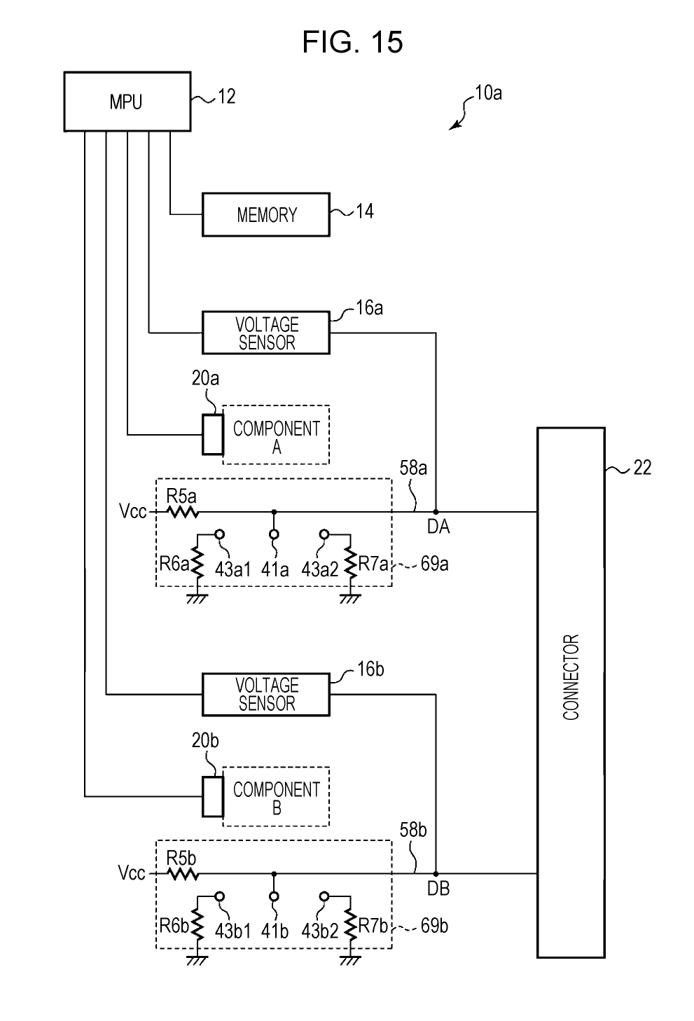

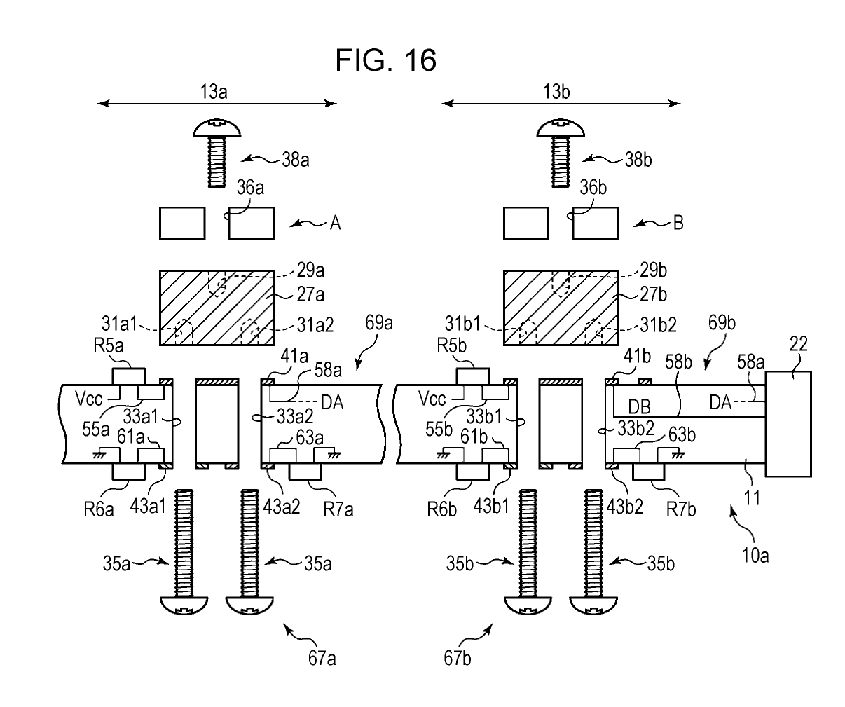

Firstly, the printed circuit board and the electronic apparatus according to the present embodiment will be described using FIGS. 15 to 26B. FIG. 15 is a block drawing that illustrates a printed circuit board according to the present embodiment. FIG. 16 is a cross-sectional view that illustrates the printed circuit board according to the present embodiment.

The electronic apparatus according to the present embodiment includes a printed circuit board 10a according to the present embodiment.

As illustrated in FIG. 15, in the same manner as the printed circuit board 10 according to the first embodiment, a printed circuit board 10a includes an MPU 12, a memory 14, voltage sensors 16a and 16b, connectors 20a and 20b and a connector 22.

A component installation region 13a, which is a region in which a component A is installed, is illustrated on the left-hand side of FIG. 16, and a component installation region 13b, which is a region in which a component B is installed, is illustrated on the right-hand side of FIG. 16.

For example, the components A and B are fixed to the printed circuit board 10a using conductive spacers (clearance ducts) 27a and 27b and the like. As the spacer 27a, for example, a double internal thread spacer or the like, in which an internal thread 29a is formed in a first side, and two internal threads 31a1 and 31a2 are formed in a second side, is used. In addition, as the spacer 27b, for example, a double internal thread spacer or the like, in which an internal thread 29b is formed in a first side, and two internal threads 31b1 and 31b2 are formed in a second side, is used. As a material of the spacers 27a and 27b, for example, stainless steel or the like is used. The dimensions of bottom surfaces of the spacers 27a and 27b are for example, configured as 3 cm×1 cm, and the heights of the spacers 27a and 27b are for example, configured to be approximately 2 cm. The internal diameters of the internal threads 29a, 31a1 and 31a2 that are formed in the spacer 27a are set to respectively accommodate the external diameters of external threads 38a and 35a that are used in screw fastening. The internal diameters of the internal threads 29b, 31b1 and 31b2 that are formed in the spacer 27b are set to respectively accommodate the external diameters of external threads (screws) 38b and 35b that are used in screw fastening.

Holes (penetration holes and holes for component fixing) 33a1, 33a2, 33b1 and 33b2 for screw fastening the spacers 27a and 27b by are formed in the component installation regions 13a and 13b. The diameters of the holes 33a1, 33a2, 33b1 and 33b2 are set to be greater than the external diameters of the screws 35a and 35b that are used in screw fastening. The holes 33a1, 33a2, 33b1 and 33b2 are clearance holes in which screw threads are not formed. In a case in which the external diameters of the screws 35a and 35b that are used in screw fastening are approximately 0.5 cm for example, the diameters of the holes 33a1, 33a2, 33b1 and 33b2 are for example, approximately 0.6 cm.

Electrodes (electrode pads) 41a and 41b are respectively formed in the component installation regions 13a and 13b on the first surface side (the upper side in FIG. 16) of the printed circuit board 10a.

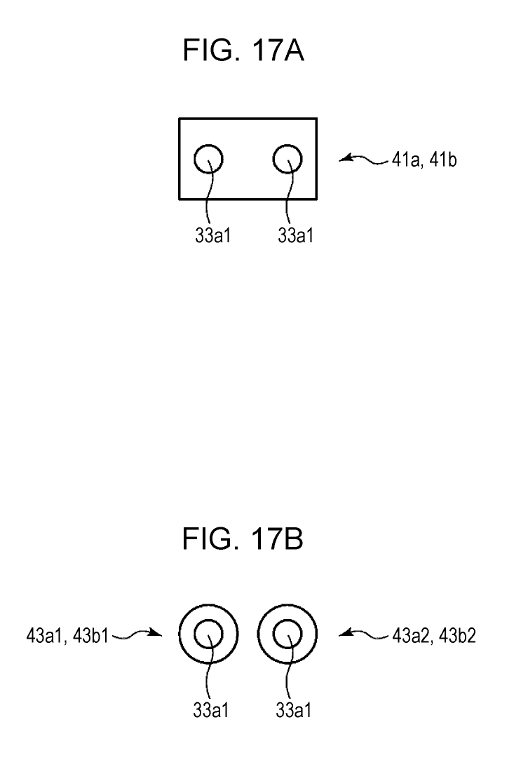

FIGS. 17A and 17B are plan views that illustrate an electrode that is formed on the printed circuit board according to the present embodiment. FIG. 17A illustrates an electrode that is formed on the first surface side of the printed circuit board according to the present embodiment.

As illustrated in FIG. 17A, the external forms of the electrodes 41a and 41b are formed to be rectangular. In addition, apertures are formed in the electrodes 41a and 41b to correspond to the holes 33a1, 33a2, 33b1 and 33b2. When the spacers 27a and 27b are arranged, lower surfaces of the spacers 27a and 27b come into contact with upper surfaces of the electrodes 41a and 41b.

Electrodes (electrode pads) 43a1 and 43a2 are formed in the component installation region 13a on a second surface side (a lower side in FIG. 16) of the printed circuit board 10a. The electrodes 43a1 and 43a2 are formed in the periphery of the holes 33a1 and 33a2.

In addition, electrodes (electrode pads) 43b1 and 43b2 are formed in the component installation region 13b on a second surface side (a lower side in FIG. 16) of the printed circuit board 10a. The electrodes 43b1 and 43b2 are formed in the periphery of the holes 33b1 and 33b2.

FIG. 17B illustrates an electrode that is formed on the second surface side of the printed circuit board according to the present embodiment.

As illustrated in FIG. 17B, the planar shapes of the electrodes 43a1, 43a2, 43b1 and 43b2 form for example, an annular shape (a ring shape).

The electrodes 41a and 41b that are formed on the surface of a first surface side of the printed circuit board 10a, that is, the upper side in FIG. 16, are respectively connected to first end terminals of resistors R5a and R5b through wiring 55a and 55b. The electrical resistances of the resistors R5a and R5b are for example, respectively configured to be approximately 1 kΩ. Second end terminals of the resistors R5a and R5b are for example, respectively set to a power-supply voltage VCC. The power-supply voltage VCC is for example, configured to be approximately 3.3 V. In addition, signal lines 58a and 58b are respectively connected to the electrodes 41a and 41b. The signal lines 58a and 58b are for outputting detection signals DA and DB using detection circuits 69a and 69b (to be described later).

The electrodes 43a1 and 43b1 are respectively electrically connected to first terminal ends of resistors R6a and R6b through wiring 61a and 61b. The electrical resistances of the resistors R6a and R6b are for example, respectively configured to be approximately 2 kΩ. Second end terminals of the resistors R6a and R6b are for example, respectively connected to a grounding potential GND.

The electrodes 43a2 and 43b2 are respectively electrically connected to first terminal ends of resistors R7a and R7b through wiring 63a and 63b. The electrical resistances of the resistors R7a and R7b are for example, respectively configured to be approximately 1 kΩ. Second end terminals of the resistors R7a and R7b are for example, respectively connected to a grounding potential GND.

When the component A is installed, screw fastening is performed in at least one of the holes 33a1 and 33a2. The screw 35a passes through either one or both of the holes 33a1 and 33a2 and screw fastening is performed. According to this configuration, the component A is fixed to the printed circuit board 10a through the spacer 27a using a member for fixing 67a that includes the screw 35a.

Additionally, when screw fastening is performed using the screw 35a, a washer (not illustrated in the drawings) may also be used. In such a case, the member for fixing 67a includes the screw 35a and the washer.

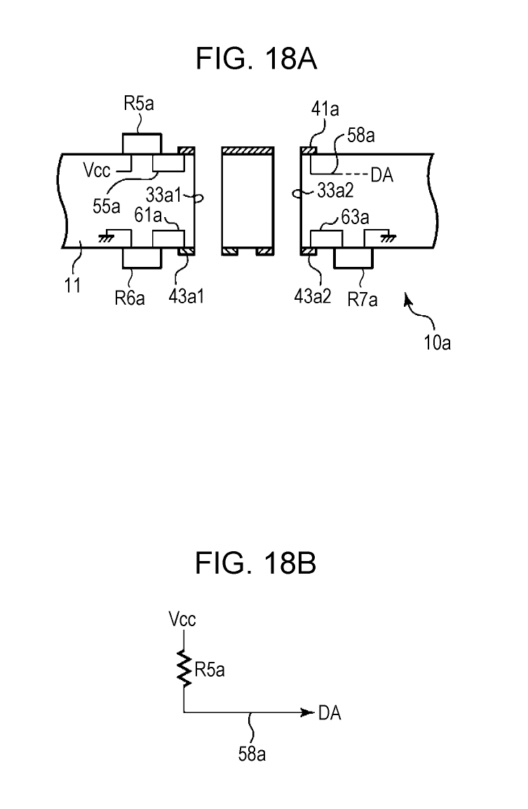

FIGS. 18A and 18B are a cross-sectional view and an equivalent circuit in a state in which the component A is not installed on the printed circuit board according to the present embodiment. FIG. 18A illustrates a cross-sectional view and FIG. 18B illustrates an equivalent circuit.

As illustrated in FIG. 18A, in a case in which the component A is not installed on the printed circuit board 10a, the spacer 27a, and the screw 35a are not attached. Therefore, the electrode 41a that is formed on an upper surface side of the printed circuit board 10a and the electrodes 43a1 and 43a2 that are formed on the lower surface side of the printed circuit board 10a are not electrically connected through the screw 35a. In this case, an equivalent circuit such as that illustrated in FIG. 18B is formed, and the voltage of the signal line 58a, that is, the voltage of the detection signal DA becomes approximately 3.3 V for example, a voltage that is equivalent to the power-supply voltage VCC for example.

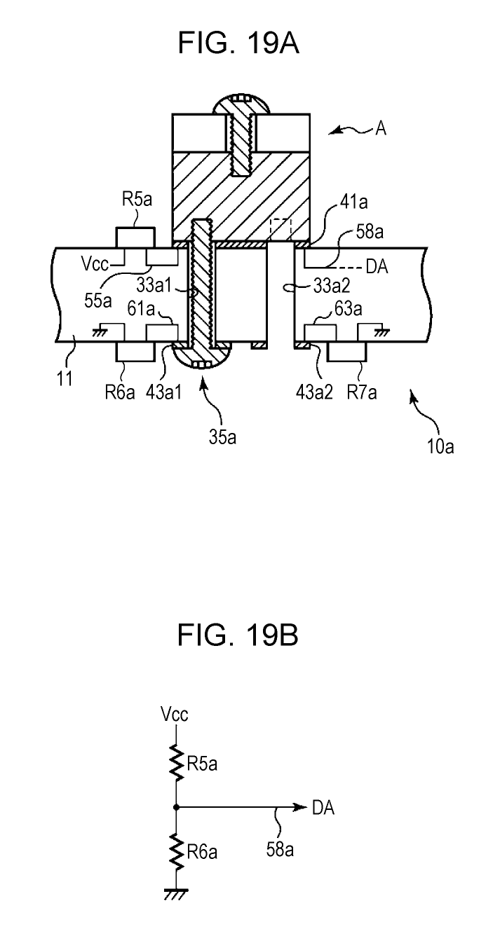

FIGS. 19A and 19B are a cross-sectional view and an equivalent circuit in a case in which screw fastening is performed in a first hole when fixing the component A to the printed circuit board according to the present embodiment. FIG. 19A illustrates a cross-sectional view and FIG. 19B illustrates an equivalent circuit.

As illustrated in FIG. 19A, in a case in which screw fastening is performed in a first hole 33a1 when the component A is fixed, the screw 35a comes into contact with the electrode 43a1. The electrode 43a1 that is formed on the lower surface side of the printed circuit board 10a and the electrode 41a that is formed on the upper surface side of the printed circuit board 10a are electrically connected through the screw 35a. In this case, an equivalent circuit such as that illustrated in FIG. 19B is formed, and the voltage of the signal line 58a, that is, the voltage of the detection signal DA becomes approximately 2.2 V for example.

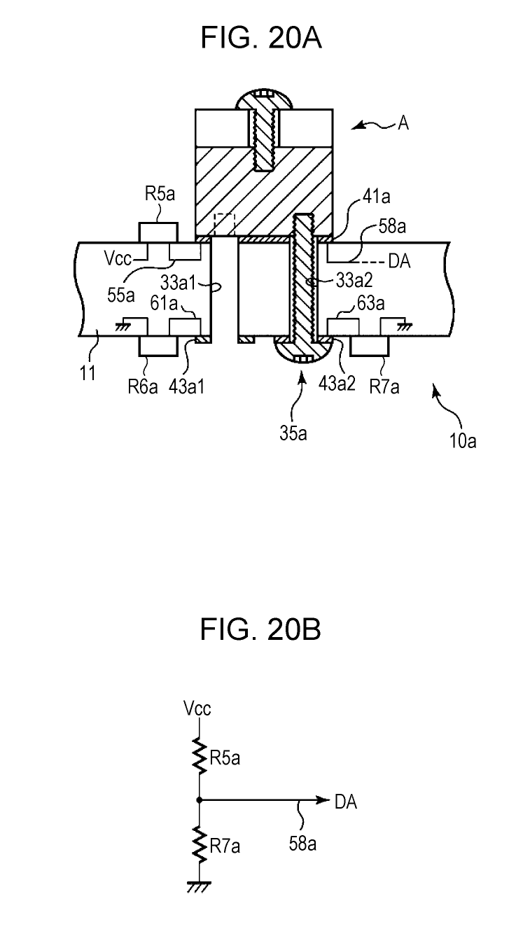

FIGS. 20A and 20B are a cross-sectional view and an equivalent circuit in a case in which screw fastening is performed in a second hole when fixing the component A to the printed circuit board according to the present embodiment. FIG. 20A illustrates a cross-sectional view and FIG. 20B illustrates an equivalent circuit.

As illustrated in FIG. 20A, in a case in which screw fastening is performed in a second hole 33a2 when the component A is fixed, the screw 35a comes into contact with the electrode 43a2. The electrode 43a2 that is formed on the lower surface side of the printed circuit board 10a and the electrode 41a that is formed on the upper surface side of the printed circuit board 10a are electrically connected through the screw 35a. In this case, an equivalent circuit such as that illustrated in FIG. 20B is formed, and the voltage of the signal line 58a, that is, the voltage of the detection signal DA becomes approximately 1.65 V for example.

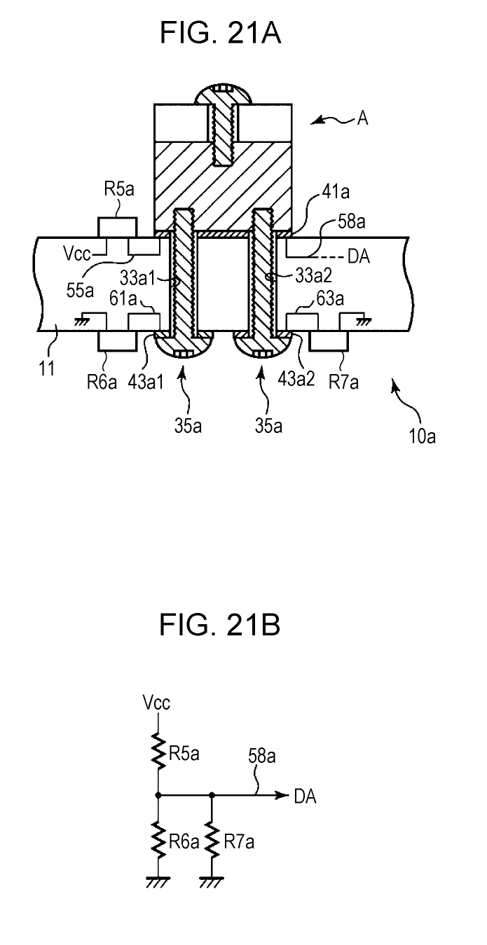

FIGS. 21A and 21B are a cross-sectional view and an equivalent circuit in a case in which screw fastening is performed in both holes when fixing the component A to the printed circuit board according to the present embodiment. FIG. 21A illustrates a cross-sectional view and FIG. 21B illustrates an equivalent circuit.

As illustrated in FIG. 21A, in a case in which screw fastening is performed in both of the holes 33a1 and 33a2 when the component A is fixed, the screws 35a come into contact with the electrodes 43a1 and 43a2. The electrodes 43a1 and 43a2 that are formed on the lower surface side of the printed circuit board 10a and the electrode 41a that is formed on the upper surface side of the printed circuit board 10a are electrically connected through the screws 35a. In this case, an equivalent circuit such as that illustrated in FIG. 21B is formed, and the voltage of the signal line 58a, that is, the voltage of the detection signal DA becomes approximately 1.32 V for example.

When the component A is installed, screw fastening is performed depending on aspects such as the kind (type) or the revision number (revision) of an installed component A.

For example, a configuration in which it is determined in advance that screw fastening is performed in the hole 33a1 for example, in a case in which a type 1 component A is installed.

In addition, for example, a configuration in which it is determined in advance that screw fastening is performed in the hole 33a2 for example, in a case in which a type 2 component A is installed.

In addition, for example, a configuration in which it is determined in advance that screw fastening is performed in both of the holes 33a1 and 33a2 for example, in a case in which a type 3 component A is installed.

Therefore, the voltage of the signal line 58a, that is, the voltage of the detection signal DA becomes a voltage that corresponds to the type of an installed component A.

When the component B is installed, screw fastening is performed in at least one of the holes 33b1 and 33b2. The screw 35b passes through either one or both of the holes 33b1 and 33b2 and screw fastening is performed. According to this configuration, the component B is fixed to the printed circuit board 10a through the spacer 27b using a member for fixing 67b that includes the screw 35b.

Additionally, when screw fastening is performed using the screw 35b, a washer (not illustrated in the drawings) may also be used. In such a case, the member for fixing 67b includes the screw 35b and the washer.

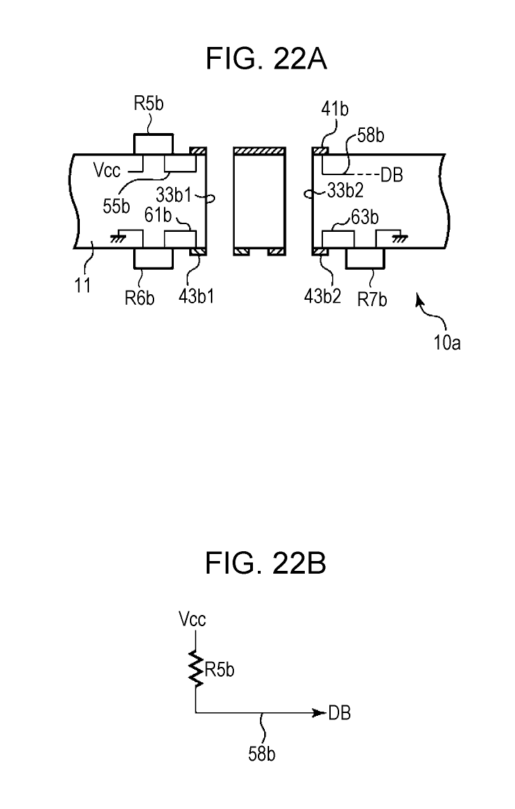

FIGS. 22A and 22B are a cross-sectional view and an equivalent circuit in a state in which the component B is not installed on the printed circuit board according to the present embodiment. FIG. 22A illustrates a cross-sectional view and FIG. 22B illustrates an equivalent circuit.

As illustrated in FIG. 22A, in a case in which the component B is not installed on the printed circuit board 10a, the spacer 27b, and the screw 35b are not attached. Therefore, the electrode 41b that is formed on an upper surface side of the printed circuit board 10a and the electrodes 43b1 and 43b2 that are formed on the lower surface side of the printed circuit board 10a are not electrically connected through the screw 35b. In this case, an equivalent circuit such as that illustrated in FIG. 22B is formed, and the voltage of the signal line 58b, that is, the voltage of the detection signal DB becomes approximately 3.3 V for example, a voltage that is equivalent to the power-supply voltage VCC for example.

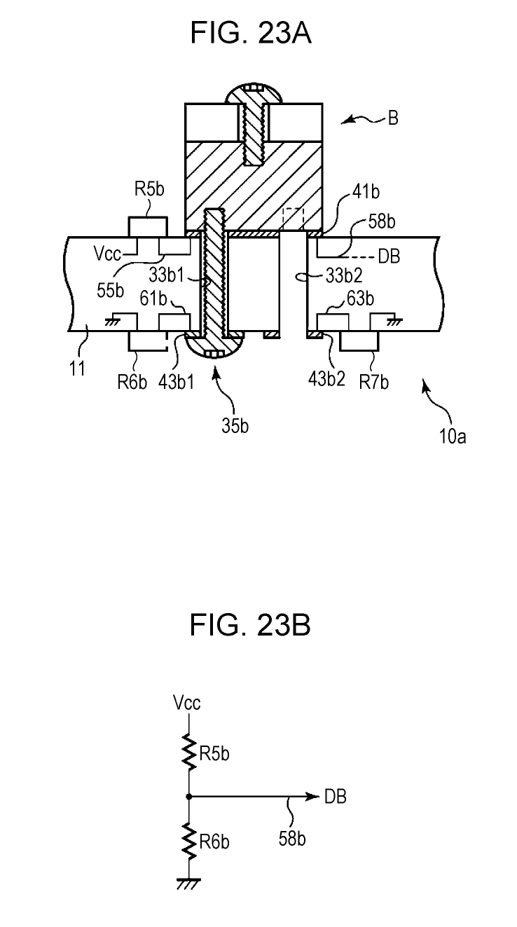

FIGS. 23A and 23B are a cross-sectional view and an equivalent circuit in a case in which screw fastening is performed in a first hole when fixing the component B to the printed circuit board according to the present embodiment. FIG. 23A illustrates a cross-sectional view and FIG. 23B illustrates an equivalent circuit.

As illustrated in FIG. 23A, in a case in which screw fastening is performed in a first hole 33b1 when the component B is fixed, the screw 35b comes into contact with the electrode 43b1. The electrode 43b1 that is formed on the lower surface side of the printed circuit board 10a and the electrode 41b that is formed on the upper surface side of the printed circuit board 10a are electrically connected through the screw 35b. In this case, an equivalent circuit such as that illustrated in FIG. 23B is formed, and the voltage of the signal line 58b, that is, the voltage of the detection signal DB becomes approximately 2.2 V for example.

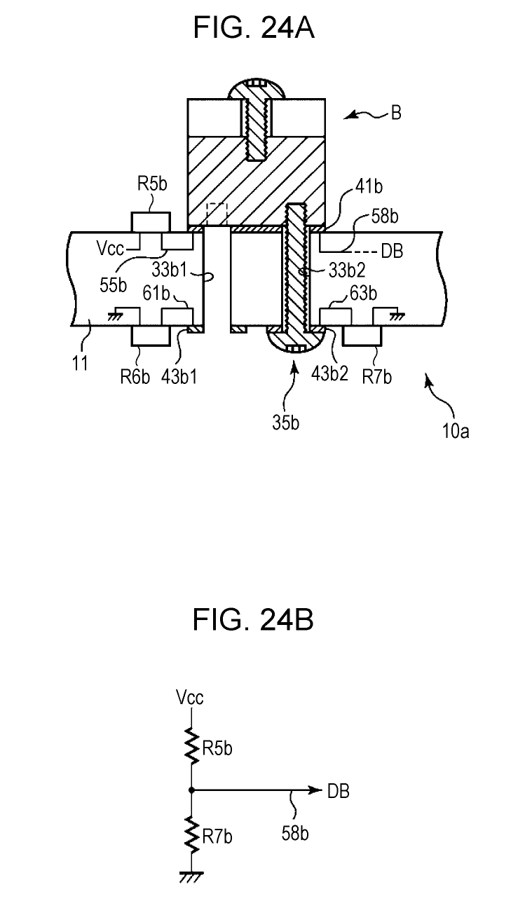

FIGS. 24A and 24B are a cross-sectional view and an equivalent circuit in a case in which screw fastening is performed in a second hole when fixing the component B to the printed circuit board according to the present embodiment. FIG. 24A illustrates a cross-sectional view and FIG. 24B illustrates an equivalent circuit.

As illustrated in FIG. 24A, in a case in which screw fastening is performed in a second hole 33b2 when the component B is fixed, the screw 35b comes into contact with the electrode 43b2. The electrode 43b2 that is formed on the lower surface side of the printed circuit board 10a and the electrode 41b that is formed on the upper surface side of the printed circuit board 10a are electrically connected through the screw 35b. In this case, an equivalent circuit such as that illustrated in FIG. 24B is formed, and the voltage of the signal line 58b, that is, the voltage of the detection signal DB becomes approximately 1.65 V for example.

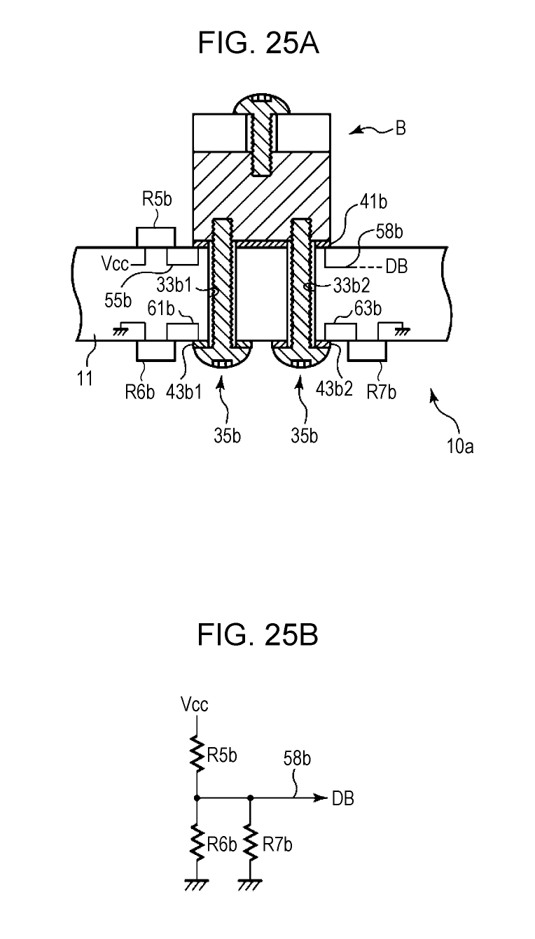

FIGS. 25A and 25B are a cross-sectional view and an equivalent circuit in a case in which screw fastening is performed in both holes when fixing the component B to the printed circuit board according to the present embodiment. FIG. 25A illustrates a cross-sectional view and FIG. 25B illustrates an equivalent circuit.

As illustrated in FIG. 25A, in a case in which screw fastening is performed in both of the holes 33b1 and 33b2 when the component B is fixed, the screws 35b come into contact with the electrodes 43b1 and 43b2. The electrodes 43b1 and 43b2 that are formed on the lower surface side of the printed circuit board 10a and the electrode 41b that is formed on the upper surface side of the printed circuit board 10a are electrically connected through the screws 35b. In this case, an equivalent circuit such as that illustrated in FIG. 25B is formed, and the voltage of the signal line 58b, that is, the voltage of the detection signal DB becomes approximately 1.32 V for example.

When the component B is installed, screw fastening is performed depending on aspects such as the kind (type) or the revision number (revision) of an installed component B.

For example, a configuration in which it is determined in advance that screw fastening is performed in the hole 33b1 for example, in a case in which a revision 1.0 component B is installed.

In addition, for example, a configuration in which it is determined in advance that screw fastening is performed in the hole 33b2 for example, in a case in which a revision 1.1 component B is installed.

In addition, for example, a configuration in which it is determined in advance that screw fastening is performed in both of the holes 33b1 and 33b2 for example, in a case in which a revision 1.2 component B is installed.

Therefore, the voltage of the signal line 58b, that is, the voltage of the detection signal DB becomes a voltage that corresponds to the type of an installed component B.

In this manner, in the present embodiment, a detection circuit (an electrical circuit) 69a that includes the electrodes 41a, 43a1 and 43a2, and the resistors R5a, R6a and R7a, and outputs a detection signal DA with a voltage depending on the presence or absence of installation of the component A and the aspect of an installed component A, is formed.

In addition, a detection circuit (an electrical circuit) 69b that includes the electrodes 41b, 43b1 and 43b2, and the resistors R5b, R6b and R7b, and outputs a detection signal DB with a voltage depending on the presence or absence of installation of the component B and the aspect of an installed component B, is formed.

As illustrated in FIG. 15, the output signal line 58a of the detection circuit 69a is connected to an input terminal end of the voltage sensor 16a. The voltage sensor 16a measures the voltage of the output signal line 58a of the detection circuit 69a, that is, the voltage of the detection signal DA, and outputs measured voltage data of the detection signal DA.

In addition, the output signal line 58b of the detection circuit 69b is connected to an input terminal end of the voltage sensor 16b. The voltage sensor 16b measures the voltage of the signal line 58b of the detection circuit 69b, that is, the voltage of the detection signal DB, and outputs measured voltage data of the detection signal DB.

The detection signals DA and DB that are output from the detection circuits 69a and 69b are output to the outside through the connector 22 in addition to being input to the voltage sensors 16a and 16b.

Tables that indicate correspondence relationships between the voltage of the detection signal DA and the aspect of the component A are stored in the memory 14.

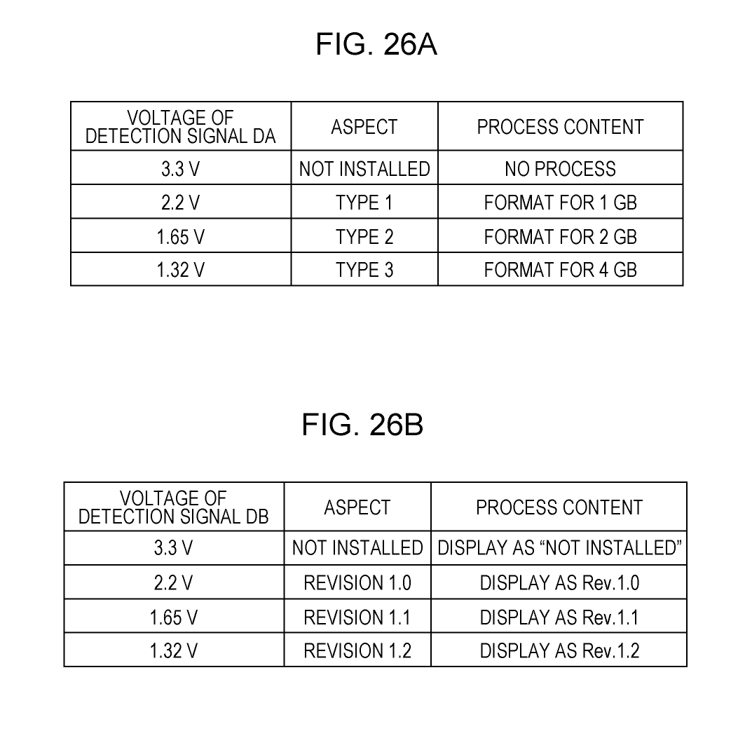

FIGS. 26A and 26B illustrate examples of tables that are stored in the memory that is mounted in the printed circuit board according to the present embodiment. FIG. 26A illustrates a table that relates to the component A.

As illustrated in FIG. 26A, process content that corresponds to the voltage of the detection signal DA of the detection circuit 69a is indicated in the table that corresponds to the component A.

In the manner mentioned above, the voltage of the detection signal DA becomes approximately 3.3 V for example, in a case in which the component A is not installed (not installed). The process content of a case in which the voltage of the detection signal DA is approximately 3.3 V is “no process”. Therefore, in this case, the MPU 12 does not perform any processes on the component A.

A type 1 component A is an SSD with a capacity of 1 GB, for example. As mentioned above, in a case in which a type 1 component A is installed, the voltage of the detection signal DA becomes approximately 2.2 V, for example. The process content of a case in which the voltage of the detection signal DA is for example, approximately 2.2 V is “format for 1 GB”. Therefore, in this case, the MPU 12 performs a process that formats the component A for 1 GB.

A type 2 component A is an SSD with a capacity of 2 GB, for example. As mentioned above, in a case in which a type 2 component A is installed, the voltage of the detection signal DA becomes approximately 1.65 V, for example. The process content of a case in which the voltage of the detection signal DA is for example, approximately 1.65 V is “format for 2 GB”. Therefore, in this case, the MPU 12 performs a process that formats the component A for 2 GB.

A type 3 component A is an SSD with a capacity of 4 GB, for example. As mentioned above, in a case in which a type 3 component A is installed, the voltage of the detection signal DA becomes approximately 1.32 V, for example. The process content of a case in which the voltage of the detection signal DA is for example, approximately 1.32 V is “format for 4 GB”. Therefore, in this case, the MPU 12 performs a process that formats the component A for 4 GB.

FIG. 26B illustrates a table that relates to the component B.

As illustrated in FIG. 26B, process content that corresponds to the voltage of the detection signal DB is indicated in the table that corresponds to the component B.

In the manner mentioned above, the voltage of the detection signal DB becomes approximately 3.3 V for example, in a case in which the component B is not installed (not installed). The process content of a case in which the voltage of the detection signal DB is approximately 3.3 V is “display not installed”. Therefore, in this case, the MPU 12 displays that the component B is “not installed” using a display screen (not illustrated in the drawings).

As mentioned above, in a case in which a revision 1.0 component B is installed, the voltage of the detection signal DB becomes approximately 2.2 V, for example. The process content of a case in which the voltage of the detection signal DB is for example, approximately 2.2 V is “display Rev. 1.0”. Therefore, in this case, the MPU 12 displays “Rev. 1.0” using the display screen.

As mentioned above, in a case in which a revision 1.1 component B is installed, the voltage of the detection signal DB becomes approximately 1.65 V, for example. The process content of a case in which the voltage of the detection signal DB is for example, approximately 1.65 V is “display Rev. 1.1”. Therefore, in this case, the MPU 12 displays “Rev. 1.1” using a display screen.

As mentioned above, in a case in which a revision 1.2 component B is installed, the voltage of the detection signal DB becomes approximately 1.32 V, for example. The process content of a case in which the voltage of the detection signal DB is for example, approximately 1.32 V is “display Rev. 1.2”. Therefore, in this case, the MPU 12 displays “Rev. 1.2” using the display screen.

The printed circuit board 10a according to the present embodiment is formed according to this configuration.

### Component Detection Method

Next, a component detection method according to the present embodiment will be described using FIG. 14.

Firstly, when the printed circuit board 10a is powered on, the MPU 12 reads firmware that is stored in the memory 14 and initiates predetermined processes (STEP 51).

Next, the MPU 12 acquires data for the voltage of the output signal line 58a of the detection circuit 69a that is measured by the voltage sensor 16a. In addition, the MPU 12 acquires data for the voltage of the output signal line 58b of the detection circuit 69b that is measured by the voltage sensor 16b (STEP S2).

Next, it is determined whether or not a component A is installed (STEP S3). Whether or not a component A is installed is determined by whether or not the voltage of the output signal line 58a of the detection circuit 69a is for example, approximately 3.3 V. More specifically, it is determined whether or not the voltage of the output signal line 58a of the detection circuit 69a is higher than a predetermined threshold voltage. For example, a voltage between 2.2 V and 3.3 V can be configured as the threshold voltage. In a case in which the voltage of the output signal line 58a of the detection circuit 69a is higher than the threshold voltage, since a component A is not installed, the MPU 12 does not perform any processes on the component A. In a case in which the voltage of the output signal line 58a of the detection circuit 69a is lower than the threshold voltage, the MPU 12 determines that a component A is installed.

In a case in which it is determined that a component A is installed, the MPU 12 determines whether or not the component A corresponds to a type 2 or a type 3 (STEP S4). Whether or not the installed component A corresponds to a type 2 or a type 3 is determined by whether or not the voltage of the output signal line 58a of the detection circuit 69a is for example, approximately 2.2 V. More specifically, it is determined whether or not the voltage of the output signal line 58a of the detection circuit 69a is higher than a predetermined threshold voltage. For example, a voltage between 1.65 V and 2.2 V can be configured as the threshold voltage. In a case in which the voltage of the output signal line 58a of the detection circuit 69a is higher than the threshold voltage, the MPU 12 determines that the component A is a type 1, and formats the component A for 1 GB (STEP S5). In a case in which the voltage of the output signal line 58a of the detection circuit 69a is lower than the threshold voltage, the MPU 12 determines that the component A corresponds to a type 2 or a type 3.

In a case in which it is determined that the component A corresponds to a type 2 or a type 3, the MPU 12 determines whether or not the component A corresponds to a type 3 (STEP S6). Whether or not the installed component A corresponds to a type 3 is determined by whether or not the voltage of the output signal line 58a of the detection circuit 69a is for example, approximately 1.65 V. More specifically, it is determined whether or not the voltage of the output signal line 58a of the detection circuit 69a is higher than a predetermined threshold voltage. For example, a voltage between 1.32 V and 1.65 V can be configured as the threshold voltage. In a case in which the voltage of the output signal line 58a of the detection circuit 69a is higher than the threshold voltage, the MPU 12 determines that the component A is a type 2, and formats the component A for 2 GB (STEP S7). In a case in which the voltage of the output signal line 58a of the detection circuit 69a is lower than the threshold voltage, the MPU 12 determines that the component A is a type 3, and formats the component A for 4 GB (STEP S8).

In a case in which determination with respect to a component B that is installed in a different location, is also desired, determination with respect to the component B in a different location is also performed subsequently.

That is, it is determined whether or not a component B is installed (STEP S9). Whether or not a component B is installed is determined by whether or not the voltage of the output signal line 58b of the detection circuit 69b is for example, approximately 3.3 V. More specifically, it is determined whether or not the voltage of the output signal line 58b of the detection circuit 69b is higher than a predetermined threshold voltage. For example, a voltage between 2.2 V and 3.3 V can be configured as the threshold voltage. In a case in which the voltage of the output signal line 58b of the detection circuit 69b is higher than the threshold voltage, since a component B is not installed, the MPU 12 displays that the component B is “not installed” using a display screen (not illustrated in the drawings) (STEP S10). In a case in which the voltage of the output signal line 58b of the detection circuit 69b is lower than the threshold voltage, the MPU 12 determines that a component B is installed.

In a case in which it is determined that a component B is installed, the MPU 12 determines whether or not the component B corresponds to a revision 1.1 or a revision 1.2 (STEP S11). Whether or not the installed component B corresponds to a revision 1.1 or a revision 1.2 is determined by whether or not the voltage of the output signal line 58b of the detection circuit 69b is for example, approximately 2.2 V. More specifically, it is determined whether or not the voltage of the output signal line 58b of the detection circuit 69b is higher than a predetermined threshold voltage. For example, a voltage between 1.65 V and 2.2 V can be configured as the threshold voltage. In a case in which the voltage of the output signal line 58b of the detection circuit 69b is higher than the threshold voltage, the MPU 12 determines that the component B is a revision 1.0, and displays that the component B is “Rev. 1.0” using the display screen (STEP S12).

In a case in which it is determined that the component B corresponds to a revision 1.1 or a revision 1.2, the MPU 12 determines whether or not the component B corresponds to a revision 1.2 (STEP S13). Whether or not the installed component B corresponds to a revision 1.2 is determined by whether or not the voltage of the output signal line 58b of the detection circuit 69b is for example, approximately 1.65 V. More specifically, it is determined whether or not the voltage of the output signal line 58b of the detection circuit 69b is higher than a predetermined threshold voltage. For example, a voltage between 1.32 V and 1.65 V can be configured as the threshold voltage. In a case in which the voltage of the output signal line 58b of the detection circuit 69b is higher than the threshold voltage, the MPU 12 determines that the component B is a revision 1.1, and displays that the component B is “Rev. 1.1” using the display screen (STEP S14).

In a case in which the voltage of the output signal line 58b of the detection circuit 69b is lower than the threshold voltage, the MPU 12 determines that the component B is a revision 1.2, and displays that the component B is “Rev. 1.2” using the display screen (STEP S15).

According to this configuration, the presence or absence of installation of the components A and B and the aspects of the kinds and revision numbers of installed components A and B are determined and processes are performed depending on the determination result.

In this manner, according to the present embodiment, the holes 33a1, 33a2, 33b1 and 33b2 for fixing the components A and B and the plurality of electrodes 43a1, 43a2, 43b1 and 43b2 are formed in the component installation regions 13a and 13b in which detachable components A and B are installed. Detection circuits 69a and 69b, which output detection signals DA and DB depending on the aspects of the electrical connections of the members for fixing 67a and 67b that are arranged in the holes 33a1, 33a2, 33b1 and 33b2 when fixing components A and B to the plurality of electrodes 43a1, 43a2, 43b1 and 43b2, are provided. The aspects of installed components A and B are associated with the holes 33a1, 33a2, 33b1 and 33b2 in which screw fastening is performed. Therefore, it is possible to easily determine the presence or absence of installation of the components A and B, the aspects of installed components A and B and the like based on the detection signals DA and DB of the detection circuits 69a and 69b. Therefore, variation of the content that is written to the memory 14 in advance for the presence or absence of installation of the components A and B and each aspect of installed components A and B, is not desired. Therefore, it is possible to suppress the generation of a plurality of kinds of printed circuit board 10a in which the information that is written to the memory 14 differs mutually, it is possible to suppress complications in the management of the printed circuit board 10a, and furthermore, it is possible to contribute to a reduction in cost.

### Modification Examples

The embodiments are not limited to the descriptions given above and various modifications can be made thereto.

For example, in the first embodiment, three sizes of electrode, large, medium and small 42La, 42Ma and 42Sa are formed, and three sizes of washer, large, medium and small, 48La, 48Ma and 48Sa are used selectively, but the embodiment is not limited thereto. Two sizes of the electrodes and washers may respectively be used, or four or more sizes of the electrodes and washers may respectively be used.

In addition, in the first embodiment, three sizes of electrode, large, medium and small 42Lb, 42Mb and 42Sb are formed, and three sizes of washer, large, medium and small, 48Lb, 48Mb and 48Sb are used selectively, but the embodiment is not limited thereto. Two sizes of the electrodes and washers may respectively be used, or four or more sizes of the electrodes and washers may respectively be used.

In addition, in the second embodiment, when fixing the component A to the printed circuit board 10a, an example of a case in which screw fastening is performed in either one or both of the holes 33a1 and 33a2, is described, but the number of holes is not limited to two. The number of holes may be one, and may be three or more. A number of internal threads that corresponds to the number of holes for screw fastening is formed in the spacer 27a.

In addition, in the second embodiment, when fixing the component B to the printed circuit board 10a, an example of a case in which screw fastening is performed in either one or both of the holes 33b1 and 33b2, is described, but the number of holes is not limited to two. The number of holes may be one, and may be three or more. A number of internal threads that corresponds to the number of holes for screw fastening is formed in the spacer 27b.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A printed circuit board comprising:
a substrate, in which a hole for fixing a component is formed, in a first region, which is a region in which the component is detachably installed;
a plurality of electrodes that are formed in the first region on the substrate; and
a detection circuit that outputs detection signal corresponding to an aspect of an electrical connection between the plurality of electrodes and a fixing member that is fixed in the hole for installing the components on the substrate.

2. The printed circuit board according to claim 1,
wherein a distance from the hole to a first electrode of the plurality of electrodes is a first dimension,
a distance from the hole to a second electrode of the plurality of electrodes is a second dimension that is greater than the first dimension, and
the detection circuit outputs the detection signal with a first voltage when a first state in which the fixing member is not electrically connected to either the first electrode or the second electrode, outputs the detection signal with a second voltage when a second state in which the fixing member is electrically connected to the first electrode and is not electrically connected to the second electrode, and outputs the detection signal with a third voltage when a third state in which the fixing member is electrically connected to the first electrode and the second electrode.

3. The printed circuit board according to claim 2,
wherein the fixing member includes a screw and a washer,
the washer for setting the second state is a washer with an external radius that is greater than the first dimension and less than the second dimension, and
the washer for setting the third state is a washer with an external radius that is greater than the second dimension.

4. The printed circuit board according to claim 3,
wherein the first electrode and the second electrode are formed on a second surface opposite to a first surface on which the component of the substrate is installed;
a third electrode is further formed in the first region on the first surface of the substrate; and
a spacer for fixing the component to the substrate is arranged on the third electrode, and the first electrode is electrically connected to the third electrode through the washer, the screw, and the spacer when the spacer is fixed to the substrate using the screw that is inserted into the hole from the second surface side of the substrate.

5. The printed circuit board according to claim 4,
wherein the detection circuit includes a first resistor that is electrically connected to the first electrode, a second resistor that is electrically connected to the second electrode, and a third resistor that is electrically connected to the third electrode.

6. The printed circuit board according to claim 1,
wherein the plurality of electrodes further includes a fourth electrode that is formed at a distance from the hole of a third dimension that is greater than the second dimension, and
the detection circuit outputs the detection signal with a fourth voltage when a fourth state in which the fixing member is electrically connected to the first electrode, the second electrode, and the fourth electrode.

7. The printed circuit board according to claim 1,
wherein a plurality of holes are formed in the first region in the substrate,
a first electrode of the plurality of electrodes is formed to correspond to a first hole of the plurality of holes,
a second electrode of the plurality of electrodes is formed to correspond to a second hole of the plurality of holes, and
the detection circuit outputs the detection signal with a first voltage when a first state in which the fixing member is not electrically connected to either the first electrode or the second electrode, outputs the detection signal with a second voltage when a second state in which the fixing member is electrically connected to the first electrode and is not electrically connected to the second electrode, outputs the detection signal with a third voltage when a third state in which the fixing member is not electrically connected to the first electrode and is electrically connected to the second electrode, and outputs the detection signal with a fourth voltage when a fourth state in which the fixing member is electrically connected both the first electrode and the second electrode.

8. The printed circuit board according to claim 7,
wherein the fixing member includes a screw,
the first electrode and the second electrode are formed on a second surface opposite to a first surface on which the component of the substrate is installed;
a third electrode is further formed in the first region on the first surface of the substrate; and
a spacer for fixing the component to the substrate is arranged on the third electrode, and the first electrode or the second electrode is electrically connected to the third electrode through the screw and the spacer when the spacer is fixed to the substrate using the screw that is inserted into the hole from the second surface side of the substrate.

9. The printed circuit board according to claim 8,
wherein the detection circuit includes a first resistor that is electrically connected to the first electrode, a second resistor that is electrically connected to the second electrode, and a third resistor that is electrically connected to the third electrode.

10. An electronic apparatus comprising:
a printed circuit board including:
a substrate, in which a hole for fixing a component is formed, in a first region, which is a region in which the component is detachably installed;
a plurality of electrodes that are formed in the first region on the substrate; and
a detection circuit that outputs detection signal corresponding to an aspect of an electrical connection between the plurality of electrodes and a fixing member that is fixed in the hole for installing the component on the substrate.

11. A component detection method that uses a printed circuit board including a substrate, in which a hole for fixing a component is formed, in a first region, which is a region in which the component is detachably installed; a plurality of electrodes that are formed in the first region on the substrate; and a detection circuit that outputs detection signal corresponding to an aspect of an electrical connection between the plurality of electrodes and a fixing member that is fixed in the hole for installing the components on the substrate, the method comprising:
detecting presence or absence of the component, or an aspect of the installed component based on the detection signal.

12. The component detection method according to claim 11,
wherein an electrical connection between the fixing member and the plurality of electrodes is set to an aspect corresponding to the component when the component is installed on the printed circuit board.
